(19) United States
(12) Patent Application Publication
(10) Pub. No.: US 2026/0198039 A1
(43) Pub. Date: Jul. 9, 2026

(54) Bifunctional Graphene Dielectrophoresis (DEP)-Graphene Field Effect Transistor (GFET) Device and Methods for Using Same

(71) Applicant: Regents of the University of Minnesota, Minneapolis, MN (US)

(72) Inventors: Steven J. Koester, Minneapolis, MN (US); Nezhueyotl Izquierdo Arriola, Minneapolis, MN (US); Ruixue Li, Minneapolis, MN (US); Sang-Hyun Oh, Minneapolis, MN (US)

(21) Appl. No.: 18/868,611

(22) PCT Filed: Jun. 8, 2023
(86) PCT No.: PCT/US2023/024808

§ 371 Date: Nov. 22, 2024

Related U.S. Application Data
(60) Provisional application No. 63/351,632, filed on Jun. 13, 2022.

(51) Int. Cl. H10D 30/47; B03C 5/00; G01N 27/414; H10D 62/10; H10D 62/80

(52) U.S. Cl. CPC H10D 30/481; G01N 27/4145; H10D 62/102; H10D 62/882; B03C 5/005; B03C 2201/26; G01N 27/4146

(57) ABSTRACT

Bifunctional graphene dielectrophoresis (DEP)-graphene field effect transistor (GFET) devices are provided. Aspects of the devices include: a graphene dielectrophoresis (DEP) component and a graphene field effect transistor (GFET) component, wherein the graphene DEP and GFET components are independently operable. Also provided are methods of evaluating a sample for the presence of an analyte, e.g., by introducing the sample into a bifunctional graphene dielectrophoresis (DEP)-graphene field effect transistor (GFET) device and obtaining a result from the device providing information as to whether the analyte is present in the sample. In addition, kits comprising the devices or systems described herein are provided. The devises, systems, methods and kits find use in a variety of different applications, including research and diagnostic applications.

### CROSS-REFERENCE TO RELATED APPLICATION

Pursuant to 35 U.S.C. § 119(e), this application claims priority to the filing date of the U.S. Provisional Patent Application Ser. No. 63/351,632, filed Jun. 13, 2022, the disclosure of which application is herein incorporated by reference.

### INTRODUCTION

Graphene-based sensors leverage physical characteristics of the material graphene to evaluate whether analyte is present in a sample. Applying graphene-based sensors to evaluate a sample can provide valuable information in the context of various applications, such as medical applications, including biomedical diagnostics. Graphene-based sensors utilizing a graphene field effect transistor (GFET) provide an effective technique for evaluating whether analyte is present in a sample, where interactions between analyte and graphene affects electrical properties of the graphene field effect transistor. Further, graphene-based techniques for applying a dielectrophoretic (DEP) force to molecules can be used to manipulate molecules. For example, applying a dielectrophoretic (DEP) force can be used to attract analyte to a graphene-based sensor in order to encourage interaction between analyte and the sensor.

Graphene-based sensors for detecting one or more analytes have been previously described. For example, graphene-based sensors are described in U.S. Patent Application Pub. No. 2019/0262827 A1, International Pub. No. WO 2012/145247 A1 and International Pub. No. WO 2019/236690 A1. Graphene-based techniques for applying a dielectrophoretic (DEP) force to attract analyte have also been previously described. For example, techniques for manipulating molecules using dielectrophoresis (DEP) are described in U.S. Patent Application Pub. No. 2018/0361400.

### SUMMARY

Despite previous efforts related to graphene-based sensor technologies, there remains room for improvement. The inventors have realized that there is a need for yet continued improvement in techniques for graphene-based sensors, such as, sensors capable of attracting target analyte and evaluating a sample for the presence of target analyte with greater sensitivity and specificity. Embodiments of the present invention satisfy this need.

Techniques for independently applying dielectrophoretic (DEP) force and evaluating the presence of analyte using a graphene field-effect transistor (GFET) where application of the DEP force is under independent control from that of the graphene field-effect transistor (GFET), e.g., via separate gate electrodes, have not been previously described to the inventors'knowledge. The inventors have realized that such techniques would offer improved detection capabilities where a graphene field-effect transistor (GFET) is deployed to evaluate the presence of analyte in a sample while a dielectrophoretic (DEP) force is applied to attract analyte, for example by increasing the concentration of target analyte locally at regions of the graphene field-effect transistor (GFET). Such configurations are capable of decreasing the limit of detection (LOD), i.e., a minimum amount of target analyte that the graphene field-effect transistor (GFET) is capable of detecting, or reducing the time required to obtain results of evaluating a sample. The independent control of the application a dielectrophoretic (DEP) force and the graphene field-effect transistor (GFET) facilitates improved detection techniques, such as by offering finer grain control of the dielectrophoretic (DEP) force (e.g., for manipulation of analyte) and the graphene field-effect transistor (GFET) (e.g., for applying different sensing regimes).

As described herein, the invention relates to bifunctional graphene dielectrophoresis (DEP)-graphene field effect transistor (GFET) devices and systems as well as methods of evaluating a sample for the presence of an analyte involving deploying such devices and systems. Embodiments of the invention described herein provide such new and useful devices, systems, methods and kits. Such devices, systems, methods and kits will aid in facilitating rapid, accurate and cost-effective sensors for use in detecting target analytes in samples, such as detecting the presence of seasonal influenza or SARS-COV-2 in samples obtained from subjects, and can be deployed at the point of care, such as at a clinic or at a subject's home.

Bifunctional graphene dielectrophoresis (DEP)-graphene field effect transistor (GFET) devices are provided. Aspects of the devices include: a graphene dielectrophoresis (DEP) component, and a graphene field effect transistor (GFET) component, wherein the graphene DEP and GFET components are independently operable. Also provided are systems comprising a bifunctional graphene dielectrophoresis (DEP)-graphene field effect transistor (GFET) device, such as those described herein, as well as a voltage source operably connected to the device. Also provided are methods for evaluating a sample for the presence of an analyte comprising: introducing the sample into a bifunctional graphene dielectrophoresis (DEP)-graphene field effect transistor (GFET) device, such as those described herein, and obtaining a result from the device providing information as to whether the analyte is present in the sample. In addition, kits comprising components of the devices and systems described herein are provided. The devices, systems, methods and kits find use in a variety of different applications, including rapid point-of-care biosensing.

### BRIEF DESCRIPTION OF THE FIGURES

FIG. 1 provides a cross-sectional view of a DEP-GFET device according to an embodiment of the invention.

FIG. 2 provides a top view of DEP-GFET device according to an embodiment of the invention.

FIG. 3 depicts a GFET-DEP device according to an embodiment of the invention that is functionalized to sense either SARS-COV-2 or influenza target analytes.

FIGS. 4A-4B depict an exemplary device array for multiplex analyte sensing according to the invention. FIG. 4A provides an example of a chip comprising an array of DEP-GFET devices without a cover. FIG. 4B provides a view of a chip comprising an array of DEP-GFET devices with a cover forming wells over each DEP-GFET device channel regions.

FIGS. 5A-5B provide example sensing modes for embodiments of the device. FIG. 5A provides an example of single-step Dirac point sensing. FIG. 5B provides an example of single-step current sensing.

FIG. 6 depicts experimental results of using a GFET-DEP device according to an embodiment of the invention for sensing the presence of analyte under various experimental conditions.

FIGS. 7A-7B provide experimental results of trapping analytes using an embodiment of a DEP-GFET device according to the present invention. FIG. 7A depicts fluorescence microscopy results of trapping analytes using a DEP-GFET device according to the present invention. FIG. 7B depicts fluorescence microscopy intensity data over time as voltage applied to the DEP-GFET device according to the present invention is modulated.

### DETAILED DESCRIPTION

Bifunctional graphene dielectrophoresis (DEP)-graphene field effect transistor (GFET) devices are provided. Aspects of the devices include: a graphene dielectrophoresis (DEP) component and a graphene field effect transistor (GFET) component, wherein the graphene DEP and GFET components are independently operable. In embodiments, the graphene DEP component comprises: a graphene layer, a source electrode electrically connected to the graphene layer, and a bottom gate electrode separated from the source electrode by a dielectric layer. In embodiments, the GFET component comprises: the graphene layer, the source electrode, a drain electrode electrically connected to the graphene layer and separated from the source electrode, and a top gate electrode separated from the graphene layer, the source and drain electrodes and the bottom gate electrode. Certain embodiments further comprise a substrate supporting the DEP component and the GFET component comprising an electrically insulating layer configured so that the bottom gate electrode is embedded within the electrically insulating layer, and a channel region located between the source and drain electrodes, wherein the graphene layer is present within the channel region and the bottom gate electrode is present beneath the channel region. Also provided are systems comprising a bifunctional graphene dielectrophoresis (DEP)-graphene field effect transistor (GFET) device and a voltage source configured to output a plurality of independent voltages and operably connected to the device.

Also provided are methods of evaluating a sample for the presence of an analyte, e.g., by introducing the sample into a bifunctional graphene dielectrophoresis (DEP)-graphene field effect transistor (GFET) device and obtaining a result from the device providing information as to whether the analyte is present in the sample. In addition, kits comprising the devices or systems described herein are provided.

Before the present invention is described in greater detail, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Certain ranges are presented herein with numerical values being preceded by the term “about.” The term “about” is used herein to provide literal support for the exact number that it precedes, as well as a number that is near to or approximately the number that the term precedes. In determining whether a number is near to or approximately a specifically recited number, the near or approximating unrecited number may be a number which, in the context in which it is presented, provides the substantial equivalent of the specifically recited number.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

While the apparatus and method has or will be described for the sake of grammatical fluidity with functional explanations, it is to be expressly understood that the claims, unless expressly formulated under 35 U.S.C. § 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 U.S.C. § 112 are to be accorded full statutory equivalents under 35 U.S.C. § 112.

In further describing various aspects of the invention, the devices, systems and components thereof are described first in greater detail, followed by a review of methods of using the devices as well as kits.

### Bifunctional Graphene Dielectrophoresis (DEP)-Graphene Field Effect Transistor (GFET) Devices And Systems

Aspects of the present disclosure include bifunctional graphene dielectrophoresis (DEP)-graphene field effect transistor (GFET) devices. In particular, the present disclosure includes bifunctional graphene dielectrophoresis (DEP)-graphene field effect transistor (GFET) devices comprising: a graphene dielectrophoresis (DEP) component and a graphene field effect transistor (GFET) component, wherein the graphene DEP and GFET components are independently operable. Each of these components is now described further in greater detail below.

### The DEP and GFET Components:

Embodiments of the device comprise a graphene DEP component and a GFET component. In embodiments, the DEP component is configured to generate a dielectrophoretic (DEP) force. That is, the DEP component may be configured such that upon application of a voltage potential, e.g., a time-varying voltage potential, to the DEP component, a strong electric field gradient is generated, which imparts a DEP force proximal to the DEP component, i.e., on nearby analyte when present. Under the influence of the DEP force, nearby analyte may be drawn towards (or driven away from) the DEP component. The magnitude and direction of the DEP force applied by the DEP component may be controlled based on characteristics of the voltage potential applied to the DEP component (e.g., frequency or magnitude of peak-to-peak voltage differential). In embodiments, the graphene DEP component comprises: a graphene layer, a source electrode electrically connected to the graphene layer, and a bottom gate electrode separated from the source electrode by a dielectric layer.

In embodiments, the GFET component is configured to act as a sensor, e.g., a biosensor. That is, the GFET component may be configured to evaluate a sample for the presence of an analyte. In embodiments, interaction between (x) graphene, e.g., a surface of a graphene layer, of the GFET component and (y) analyte present in a sample, affects electrical properties of the GFET, e.g., causes changes in current (e.g., drain current) or voltage, or relationships therebetween, at different features of the GFET component or other properties (e.g., a Dirac point) of the GFET component. In embodiments, such changes in electrical properties of the GFET component are monitored to provide information about the presence of analyte in a sample. In embodiments, such changes in electrical properties of the GFET produce, or are manipulated (e.g., amplified, filtered, digitized or otherwise modified) to produce, a readable signal conveying information about the presence of analyte in a sample. Information about the presence of analyte in a sample includes, e.g., information about the presence or absence or amount or relative amount of analyte present in a sample. In embodiments, the GFET component comprises: the graphene layer, the source electrode, a drain electrode electrically connected to the graphene layer and separated from the source electrode and a top gate electrode separated from the graphene layer, the source and drain electrodes and the bottom gate electrode.

In embodiments of the device, the graphene DEP component and the GFET component are independently operable. By “independently operable,” it is meant that the device can be configured to operate: (i) in a DEP regime only, i.e., such that the device generates a DEP force for attracting and trapping target analyte; (ii) in a GFET regime only, i.e., such that the device behaves as a field effect transistor, such as may be used for evaluating the presence of analyte in a sample by means of, e.g., Dirac point sensing or current sensing, as such are described in detail below; or (iii) in a combined DEP and GFET regime, i.e., such that the device simultaneously attracts and traps target analyte using the DEP component for DEP trapping and uses the GFET component to evaluate a sample for the presence of target analyte. As described in detail below, the presence of a separate top gate and bottom gate, each independently operable, facilitates embodiments of the device to be operated in each of a DEP regime only, a GFET regime only and a combined DEP and GFET regime, i.e., for the device to be independently operable.

### Graphene Layer:

In embodiments, both the DEP component and the GFET component comprise a graphene layer, which graphene layer is common to both components. In embodiments, the graphene layer is a thin layer comprised of the material graphene. Graphene is a two-dimensional form of carbon, i.e., comprising sp²-bonded carbon atoms arranged in a two-dimensional honeycomb structure. Graphene can be realized in monolayer form through, for example, mechanical exfoliation or through growth on copper using chemical vapor deposition (CVD). In embodiments, the graphene layer of the device may comprise one or more layers of graphene (i.e., multiple layers of graphene stacked on top of each other), such as, for example, a single layer of graphene, two layers of graphene (i.e., bilayer graphene) or three or more layers of graphene. In embodiments, the graphene layer may have a thickness of 0.3 nm to 2 nm, such as 0.3 nm to 0.6 nm or 0.3 nm to 1 nm. In some cases, the graphene layer can have a thickness on the order of 0.3 nm. In embodiments, the graphene layer may have a width of 0.1 μm to 20 μm. In embodiments, the graphene layer may have a length of 1 μm to 1 mm, such as 50 to 100 μm. In embodiments, the length of the graphene layer may be configured to substantially match the length of a channel region of the device, e.g., as described below. The graphene layer may be present on the device in a single strip of graphene or in a plurality of laterally spaced strips of graphene, such as one to 500 or more strips, e.g., one strip or two strips or three strips or four strips or five strips or ten strips or 50 strips or 100 strips or 200 strips or 300 strips or 400 strips or 500 strips or more. As described in detail below, configuring the graphene layer as a plurality of strips of graphene may enhance the capacity of the device to apply a DEP force and thereby to attract and trap analyte. In other cases, reducing the number of strips of graphene that comprise the graphene layer, in some cases, in conjunction with reducing the number of strips or “fingers” of the bottom gate electrode, as described below, may be preferable, e.g., for improving signal to noise characteristics of the device. For example, a device comprising a graphene layer that is a single strip of graphene, in some cases, in conjunction with a single strip or “finger” of the bottom gate electrode, as described below, may exhibit improved signal to noise characteristics of the device.

### Dielectric Layer:

In embodiments, the DEP component of the device comprises a dielectric layer. In embodiments, the dielectric layer is configured such that the graphene layer is disposed on one or more sections of, e.g., strips of, the top surface of the dielectric layer of the device. In such embodiments, the graphene layer may form a very thin top layer on one or more sections of, e.g., strips of, the dielectric layer of the device. The dielectric layer may be comprised of any convenient material that is an electrical insulator. In embodiments, the dielectric layer may be comprised of a material selected to minimize electrical and/or chemical interactions with the graphene layer of the device. In embodiments, the dielectric layer is formed from a dielectric material. In some cases, the dielectric layer is formed from a high-k material. In some cases, the dielectric layer is formed from silicon oxide, hafnium oxide, hafnium dioxide, hafnium silicate, zirconium oxide, zirconium silicate, titanium oxide, zinc oxide, boron nitride, aluminum oxide, silicon nitride, indium oxide or tin oxide. In some cases, the dielectric layer is formed from an alloy including one or more of oxygen, silicon, hafnium, zirconium, titanium, zinc, boron, nitrogen or aluminum. In embodiments, alloys of interest may comprise cation or anion species of materials. For example, in embodiments, the dielectric layer may be formed from hafnium oxynitrate. The dielectric layer may have a thickness of 1 nm to 100 nm, such as 1 nm or 2 nm or 3 nm or 4 nm or 5 nm or 6 nm or 7 nm or 8 nm or 9 nm or 10 nm or 20 nm or 30 nm or 40 nm or 50 nm or 60 nm or 70 nm or 80 nm or 90 nm or 100 nm. In some embodiments, the dielectric layer has a thickness of approximately 10 nm. In some cases, the dielectric layer may have a thickness that is less than 20 nm. In embodiments, the dielectric layer may be configured to improve voltage requirements versus DEP force characteristics, i.e., such that lower voltages are required (i.e., voltage applied to the bottom gate electrode) to provide greater DEP forces. The dielectric layer may have any convenient shape and dimensions, e.g., length and width, and such may vary as needed. In embodiments, the length and width of the dielectric layer may span, or substantially span, the length and width of the device or the length and width of a plurality of devices present on a single substrate, as described below. In embodiments, the shape and dimensions, e.g., length and width, of the dielectric layer may be selected so that the dielectric layer is always present above the bottom gate of the device, e.g., configured to ensure that the graphene layer does not electrically short to the bottom gate. In embodiments, the dielectric constant characterizing the dielectric layer is greater than four, such as for example, four or five or six or seven or eight or nine or ten or 20 or 50 or more.

### Bottom Gate:

In embodiments, the DEP component of the device comprises a bottom gate electrode, i.e., a bottom gate, such that the bottom gate electrode itself is a gate feature, in particular a bottom gate feature, of the DEP component. In embodiments, the bottom gate electrode is configured such that the bottom gate is disposed below the dielectric layer of the device and therefore also below the graphene layer of the device. In some embodiments, the bottom gate electrode is present immediately below the dielectric layer such that the bottom gate is in contact with the dielectric layer, i.e., a top surface of the bottom gate electrode is in contact with a bottom surface of the dielectric layer.

In embodiments, the bottom gate electrode is configured so that the bottom gate electrode crosses below the graphene layer of the device, separated by the dielectric layer. Crossings of the bottom gate electrode and the graphene layer may be configured to creates at least one “edge,” meaning a side region of the graphene layer that extends over (i.e., crosses over) the bottom gate electrode. Such edge regions are of interest insofar as the dielectrophoretic (DEP) force generated by the device may be maximized at or near such edge regions due at least in part to interaction between the electrical field resulting from applying a voltage bias to the bottom gate and the graphene layer. In some cases, the bottom gate electrode and the graphene layer are arranged to maximize the number of crossings of the bottom gate electrode and the graphene layer. That is, embodiments may be configured to maximize the number of edges, as described above, in order to maximize the magnitude of the DEP force generated by the device and therefore maximize the potential for attracting and trapping target analyte. In certain embodiments, the bottom gate electrode is configured to form “fingers” or electrically interconnected strips, i.e., the bottom gate electrode is configured in an interdigitated fashion. The “fingers” or strips of the bottom gate electrode may be arranged substantially orthogonally with one or more strips of graphene that make up the graphene layer of the device. As described above, in certain cases, reducing the number of crossings and edges between the bottom gate electrode and the graphene layer may be preferable, e.g., for improving signal to noise characteristics of the device. For example, a device comprising a bottom gate electrode that is a single strip or “finger,” in some cases, in conjunction with a graphene layer that comprises a single strip of graphene, as described above, may be preferable for improving signal to noise characteristics of the device.

In embodiments, the bottom gate electrode is formed from an electrically conductive material. In some cases, the bottom gate electrode is formed from electrically conductive metals, silicides or alloys. For example, the bottom gate electrode may be formed from, gold, silver, palladium, platinum, tungsten, chromium, titanium, aluminum, copper, molybdenum, iridium or alloys or silicides of such metals. In some cases, the bottom gate electrode may be formed from metallic nitrides, such as titanium nitride, tantalum nitride or other nitride metallics. In other cases, the bottom gate electrode may be formed from chalcogenides; i.e., materials that contain one or more chalcogen element, typically sulfides, selenides, and tellurides. In still other cases, the bottom gate electrode may be formed from transition metals, such as group six metals. In embodiments, the bottom gate electrode may be formed from the same material as one or more of the source electrode or the drain electrode or the top gate electrode. In some cases, the bottom gate electrode may be formed from a monolayer material, i.e., a two-dimensional material. In some cases, the bottom gate electrode may have a thickness of up to 5 μm, such as less than 1 nm or 2 nm or 3 nm or 4 nm or 5 nm or 6 nm or 7 nm or 8 nm or 9 nm or 10 nm or 100 nm or 200 nm or 300 nm or 400 nm or 500 nm or 600 nm or 700 nm or 800 nm or 900 nm or 1 μm or 2 μm or 3 μm or 4 μm or 5 μm. In embodiments, the dimensions, e.g., length and width, of the bottom gate electrode may be any convenient dimensions and may vary. In embodiments, the dimensions, e.g., length and width of the bottom gate electrode may be configured to span the entire distance between the source and drain, as described below. In embodiments, the length of the bottom gate electrode may be, for example, up to 1 mm, such as 1 μm or 10 μm or 100 μm or 500 μm or 1 mm and the width of the bottom gate electrode may be, for example, up to 1 mm, such as 1 μm or 10 μm or 100 μm or 500 μm or 1 mm. In embodiments, each interdigitated finger or strip of the bottom gate may have any convenient length and width as desired to span the distance between the source and drain.

### Source:

In embodiments, both the DEP component and the GFET component comprise a source electrode, i.e., a source, such that the source electrode itself is a source feature of the GFET and/or DEP components, where the source electrode is electrically connected to the graphene layer. In embodiments, the source electrode is configured such that it is disposed on the top surface of a section of the dielectric layer. In some embodiments, the source electrode abuts the graphene layer, or, in other embodiments, the source electrode is disposed on top of the graphene layer, i.e., as a layer on top of one or both of the graphene layer and the dielectric layer. In embodiments, the source electrode is electrically connected with the graphene layer. For example, the source electrode may be electrically connected to one side of the one or more strips of graphene that comprise the graphene layer.

In embodiments, the source electrode is separated from the bottom gate electrode. In such embodiments, the source electrode is configured to be electrically insulated, or substantially electrically insulated, from the bottom gate electrode such that the source and the bottom gate are capable of being operated independently, i.e., such that different voltage biases or current sources may be applied to each of the source and bottom gate electrodes.

In embodiments, the source electrode is formed from an electrically conductive material. In some cases, the source is formed from electrically conductive metals, silicides or alloys. For example, the source may be formed from gold, silver, palladium, platinum, tungsten, chromium, titanium, aluminum, copper, molybdenum, iridium or alloys or silicides of such metals. In some cases, the source electrode may be formed from metallic nitrides, such as titanium nitride, tantalum nitride or other nitride metallics. In other cases, the source electrode may be formed from chalcogenides; i.e., materials that contain one or more chalcogen element, typically sulfides, selenides, and tellurides. In still other cases, the source electrode may be formed from transition metals, such as group six metals. In embodiments, the source electrode may be formed from the same material as one or more of the bottom gate electrode or the drain electrode or the top gate electrode. In some cases, the source electrode may be formed from a monolayer material, i.e., a two-dimensional material. In some cases, the source electrode may have a thickness of up to 5 μm, such as less than 1 nm or 2 nm or 3 nm or 4 nm or 5 nm or 6 nm or 7 nm or 8 nm or 9 nm or 10 nm or 100 nm or 200 nm or 300 nm or 400 nm or 500 nm or 600 nm or 700 nm or 800 nm or 900 nm or 1 μm or 2 μm or 3 μm or 4 μm or 5 μm. In embodiments, the dimensions, e.g., length and width, of the source electrode may be any convenient length and width and such may vary. In embodiments, the length of the source electrode may be, for example, up to 1 mm, such as 1 μm or 10 μm or 100 μm or 500 μm or 1 mm and the width of the source electrode may be, for example, up to 1 mm, such as 1 μm or 10 μm or 100 μm or 500 μm or 1 mm.

### Drain:

In embodiments, the GFET component comprises a drain electrode, i.e., a drain, where the drain electrode is electrically connected to the graphene layer. In embodiments, the drain electrode is configured such that it is disposed on the top surface of a section of the dielectric layer. In some embodiments, the drain electrode abuts the graphene layer, or, in other embodiments, the drain electrode is disposed on top of the graphene layer, i.e., as a layer on top of one or both of the graphene layer and the dielectric layer. In embodiments, the drain electrode is electrically connected with the graphene layer. For example, the drain electrode may be electrically connected to one side of the one or more strips of graphene that comprise the graphene layer. In embodiments, the drain electrode is electrically connected to a section of the graphene layer that is separate from, in some cases symmetrical with or opposite from, a section of the graphene layer that is connected to the source electrode. That is, the source and the drain electrodes are not directly connected to each other but may be indirectly connected via the graphene layer.

In embodiments, the drain electrode is separated from the source electrode, e.g., separated via the graphene layer. In such embodiments, the drain electrode is configured to be electrically insulated, or substantially electrically insulated, from the source electrode such that the drain and the source are capable of being operated independently, i.e., such that different voltage or current sources may be applied to each of the drain and source electrodes.

Notwithstanding the foregoing, the source and the drain electrodes may be separated from each other via the graphene layer.

Similarly, in embodiments, the drain electrode is also separated from the bottom gate electrode. In such embodiments, the drain electrode is configured to be electrically insulated, or substantially electrically insulated, from the bottom gate electrode such that the drain and the bottom gate are capable of being operated independently, i.e., such that different voltage potentials or current sources may be applied to each of the drain and bottom gate electrodes.

In embodiments, the drain electrode is formed from an electrically conductive material. In some cases, the drain is formed from electrically conductive metals, silicides or alloys. For example, the drain may be formed from gold, silver, palladium, platinum, tungsten, chromium, titanium, aluminum, copper, molybdenum, iridium or alloys or silicides of such metals. In some cases, the drain electrode may be formed from metallic nitrides, such as titanium nitride, tantalum nitride or other nitride metallics. In other cases, the drain electrode may be formed from chalcogenides; i.e., materials that contain one or more chalcogen element, typically sulfides, selenides, and tellurides. In still other cases, the drain electrode may be formed from transition metals, such as group six metals. In embodiments, the drain electrode may be formed from the same material as one or more of the bottom gate electrode or the source electrode or the top gate electrode. In some cases, the drain electrode may be formed from a monolayer material, i.e., a two-dimensional material. In some cases, the drain electrode may have a thickness of up to 5 μm, such as less than 1 nm or 2 nm or 3 nm or 4 nm or 5 nm or 6 nm or 7 nm or 8 nm or 9 nm or 10 nm or 100 nm or 200 nm or 300 nm or 400 nm or 500 nm or 600 nm or 700 nm or 800 nm or 900 nm or 1 μm or 2 μm or 3 μm or 4 μm or 5 μm. In embodiments, the dimensions, e.g., length and width, of the drain electrode may be any convenient length and width and such may vary. In embodiments, the length of the drain electrode may be, for example, up to 1 mm, such as 1 μm or 10 μm or 100 μm or 500 μm or 1 mm and the width of the drain electrode may be, for example, up to 1 mm, such as 1 μm or 10 μm or 100 μm or 500 μm or 1 mm. In embodiments, the configuration, e.g., the material, length, width and/or thickness, of the drain electrode may be substantially the same as the corresponding characteristics of the source electrode such that the two electrodes share substantially similar electrical properties, such as, for example, a resistance.

### Top Gate:

In embodiments, the GFET component of the device comprises a top gate electrode. The top gate electrode may be configured such that upon application of a fluid, e.g., an electrolyte solution, contacting the top gate electrode and the graphene layer, the top gate electrode and the fluid comprise a top gate of the GFET component. That is, in embodiments, the top gate electrode is configured to be a metal contact to such electrolyte solution top gate.

In embodiments, the top gate electrode is configured such that it is separated from the graphene layer, the source and drain electrodes and the bottom gate electrode. In such embodiments, the top gate electrode is configured to be electrically insulated, or substantially electrically insulated, from the graphene layer. In such embodiments, the top gate electrode is configured to be electrically insulated, or substantially electrically insulated, from the source electrode such that the top gate electrode and the source are capable of being operated independently, i.e., such that different voltage biases or current sources may be applied to each of the top gate and source electrodes. Similarly, in embodiments, the top gate electrode is configured to be electrically insulated, or substantially electrically insulated, from the drain electrode such that the top gate electrode and the drain are capable of being operated independently, i.e., such that different voltage biases or current sources may be applied to each of the top gate and drain electrodes.

In addition, in embodiments, the top gate electrode is also separated from the bottom gate electrode. In such embodiments, the top gate electrode is configured to be electrically insulated, or substantially electrically insulated, from the bottom gate electrode such that the top gate and the bottom gate are capable of being operated independently, i.e., such that different voltage potentials or current sources may be applied to each of the top gate and bottom gate electrodes. As such, the device may be configured to have two independently operable gates, a top gate and a bottom gate, each influencing aspects of the graphene layer of the device.

In embodiments, the top gate electrode is disposed on the top surface of the dielectric layer, e.g., such that a bottom surface of the top gate electrode is in contact with a section of the top surface of the dielectric layer. In other embodiments, the top gate electrode is disposed directly on a device substrate, as such aspect of the device is described below.

In embodiments, the top gate electrode is formed from an electrically conductive material. In some cases, the top gate electrode is formed from electrically conductive metals, silicides or alloys. For example, the top gate electrode may be formed from gold, silver, palladium, platinum, tungsten, chromium, titanium, aluminum, copper, molybdenum, iridium or alloys or silicides of such metals. In some cases, the top gate electrode may be formed from metallic nitrides, such as titanium nitride, tantalum nitride or other nitride metallics. In other cases, the top gate electrode may be formed from chalcogenides; i.e., materials that contain one or more chalcogen element, typically sulfides, selenides, and tellurides. In still other cases, the top gate electrode may be formed from transition metals, such as group six metals. In embodiments, the top gate electrode may be formed from the same material as one or more of the source electrode or the drain electrode or the bottom gate electrode. In some cases, the top gate electrode may be formed from a monolayer material, i.e., a two-dimensional material. In some cases, the top gate electrode may have a thickness of up to 5 μm, such as less than 1 nm or 2 nm or 3 nm or 4 nm or 5 nm or 6 nm or 7 nm or 8 nm or 9 nm or 10 nm or 100 nm or 200 nm or 300 nm or 400 nm or 500 nm or 600 nm or 700 nm or 800 nm or 900 nm or 1 μm or 2 μm or 3 μm or 4 μm or 5 μm. In embodiments, the dimensions, e.g., length and width, of the top gate electrode may be any convenient length and width and such may vary. In embodiments, the length of the top gate electrode may be, for example, up to 1 mm, such as 1 μm or 10 μm or 100 μm or 500 μm or 1 mm and the width of the top gate electrode may be, for example, up to 1 mm, such as 1 μm or 10 μm or 100 μm or 500 μm or 1 mm. In embodiments, the top gate electrode may be configured, i.e., positioned on the device, such that fluid comprising a liquid top gate, e.g., electrolyte solution that functions with the top gate electrode as the top gate, present on the device is in contact with both the top gate electrode as well as other features of the device, in particular, the graphene layer of the device. In embodiments, the top gate electrode may be configured so that fluid present on the device, in contact with and/or covering the graphene layer of the device, is also in contact with the top gate electrode.

### Substrate:

In embodiments, the device comprises a substrate configured to support the DEP component and the GFET component. That is, the substrate may be configured so that the features of the DEP component and the GFET component are arranged on, i.e., fixed in a predetermined position on, the substrate. In embodiments, the substrate comprises an electrically insulating layer configured so that the bottom gate electrode is embedded within the electrically insulating layer. That is, the bottom gate electrode may be embedded into the substrate such that, as described above, the bottom gate electrode is disposed on the device such that a top surface of the bottom gate electrode is in contact with a bottom surface of the dielectric layer. The substrate may be configured so that it is an electrical insulator or otherwise does not influence, or does not substantially influence, the electrical properties of the DEP or GFET components.

In embodiments, the substrate is formed from an electrically insulating material or substantially electrically insulating material. In some cases, the substrate is formed from quartz, sapphire, glass or another suitable electrically insulating material or combinations thereof. In embodiments, the substrate is formed from materials such as silicon or silicon oxide or a combination of such materials, such as, for example, a silicon oxide layer disposed on top of a silicon layer. In embodiments, the substrate is formed from a material that differs, e.g., has a different dielectric constant, than the dielectric layer.

In embodiments, the substrate is coextensive with the length and width of the device. In embodiments, the substrate is coextensive with the length and width of the dielectric layer. In some embodiments, the dielectric layer is disposed immediately on top of the substrate, such that a top surface of the substrate is in contact with a bottom surface of the dielectric layer. The substrate may have a thickness of 100 μm to 5 mm, such as 100 μm or 200 μm or 300 μm or 400 μm or 500 μm or 600 μm or 700 μm or 800 μm or 900 μm or 1 mm or 2 mm or 3 mm or 4 mm or 5 mm. The substrate may be configured as any convenient shape, such as, for example, when viewed from above, i.e., a top view, a square or a rectangle. The substrate may have any convenient shape and dimensions, e.g., length and width, and such may vary, i.e., such that the substrate is configured to support a single device or a plurality of devices. In some instances, the length of the substrate may be configured to accommodate a device length of, for example, up to 1 mm, such as 1 μm or 10 μm or 100 μm or 500 μm or 1 mm and the width of the substrate may be configured to accommodate a device length of, for example, up to 1 mm, such as 1 μm or 10 μm or 100 μm or 500 μm or 1 mm. In embodiments, the substrate may have substantially greater length and width than a device and such substrate may be configured to support a plurality of devices.

### Channel Region:

In embodiments, the device comprises a channel region located between the source and drain electrodes, wherein the graphene layer is present within the channel region and the bottom gate electrode is present beneath the channel region. That is, the channel region may be defined by a space between the source and drain electrodes, in which the graphene layer is present as well as the bottom gate electrode, which is located beneath the graphene layer. In embodiments, the channel region is configured as a space where a surface of the graphene layer is exposed. In particular, a surface of the graphene region may be exposed such that fluid present in the channel region (e.g., electrolyte solution comprising a liquid top gate) comes into contact with the exposed surface of the graphene region. In embodiments, the channel region may be configured such that liquid present on the device may flow to the channel region. Such configurations facilitate interaction between the graphene region and the liquid top gate, i.e., target analyte present in the liquid top gate. In such embodiments, the channel region comprises a space where the edges formed by crossings between the graphene layer and the bottom gate electrode, i.e., as described above, are present.

In embodiments in which the graphene layer is comprised of a plurality of strips of graphene, one side of each strip of graphene is electrically connected to the source electrode and the other side of the strip of graphene is electrically connected to the drain electrode. In such embodiments, the channel region is defined as the space between the source and the drain electrodes. That is, the source and drain electrodes may straddle both sides of the channel region with the graphene layer connected to the source and drain electrodes on either side of the channel region and the bottom gate electrode present beneath the channel region between the source and drain electrodes. Typically, in such embodiments, the source and the drain electrodes have a thickness, or height that extends above the substrate and the dielectric layer that is greater than the thickness, or height of, the graphene layer such that a well-like space is formed between the source and the drain electrodes that comprises the channel region.

In embodiments, the channel region is configured to receive fluid. In such embodiments, such fluid may function as a top gate of the device. As described above, the top gate electrode is configured to be a contact between fluid contacting both the top gate electrode and the graphene layer. By “configured to receive fluid,” it is meant that the channel region is configured such that fluid, such as a fluid droplet of sufficient volume, present in the channel region comes into contact with the graphene layer, for example, substantially covers the entirety of the graphene layer, and, in addition, comes into contact with the top gate electrode. In embodiments, the top gate electrode is configured to electrically influence fluid present in the channel region. That is, the channel region and the top gate may be configured to enable, for example, an electrical potential, e.g., applied by a voltage source, applied to the top gate electrode to influence the electrical potential of fluid present in the channel region. Application of a voltage bias to the top gate can, in turn, influence the electrical properties of the graphene layer of the device. In such embodiments, the top gate electrode and the fluid present in the channel region comprise a top gate.

Embodiments of the device according to the present invention may further comprise an electrical passivation layer present on the source and drain electrodes. By “electrical passivation layer,” it is meant covering the source and drain electrodes with an insulating layer, i.e., a layer if material configured to electrically isolate the source and drain electrodes. In particular, the electrical passivation layer may be configured to electrically isolate the source and drain electrodes from the top gate. That is, the electrical passivation layer may be configured to minimize current leakage from either the source or the drain through fluid present in the channel region of the device. As such, the electrical passivation layer may be configured so that the source and/or drain electrodes may be operated independently from the top gate electrode, i.e., different voltage potentials may be independently applied to each of the source, drain and top gate electrodes. In embodiments, the electrode passivation layer is deposited over the contact metal electrodes of the source and drain to minimize gate leakage. (The bottom gate electrode, being disposed below the dielectric layer, an electrical insulator, may also have a separate voltage potential applied to it, independent of voltage potentials applied to any of the source, drain and top gate electrodes.) In embodiments, the electrical passivation layer is formed from an electrically insulating material. For example, the electrical passivation layer may be formed from silicon dioxide, aluminum oxide, hafnium oxide or the like. The electrical passivation layer may be substantially co-extensive with each of the source and drain electrodes (i.e., may cover the entirety of each such electrode) and may have a thickness of 5 nm to 1 μm, such as 5 nm or 10 nm or 20 nm or 30 nm or 40 nm or 50 nm or 60 nm or 70 nm or 80 nm or 90 nm or 100 nm or 200 nm or 300 nm or 400 nm or 500 nm or 600 nm or 700 nm or 800 nm or 900 nm or 1 μm. In some embodiments, an electrical passivation layer may be present on a portion of the graphene layer, such as, for example, one or more edge regions of the graphene layer (e.g., edges of the graphene layer corresponding to regions where the graphene layer crosses the bottom gate electrode) present in the channel region of the device. In such cases, the electrical passivation layer may be configured to protect an area of the graphene layer from damage, e.g., damage during use of the device such that the electrical passivation later extends the useful life of the device.

As described above, the channel region may be configured to facilitate interaction between the graphene layer and the liquid top gate, including, target analyte, if any, present in the liquid top gate (i.e., when a biological sample is added to an electrolyte solution used as a liquid top gate of the device). Further, in embodiments, the channel region may be configured such that application of dielectrophoretic (DEP) force by the DEP component of the device can attract target analyte present in the liquid top gate to the channel region, in particular, attract target analyte to an exposed surface of the graphene layer present in the channel region. In some cases, interaction between target analyte present in the liquid top gate with the exposed surface of the graphene layer affects the electrical properties of the graphene layer. In embodiments, such interaction, and the resulting changes in electrical properties of the device, enables the device to evaluate the presence of target analyte present in the liquid top gate. Exemplary changes to the electrical properties of the graphene layer and the device include, for example, changes to the magnitude of current flowing between the source and drain electrodes, i.e., via the graphene layer of the device, caused by the presence of target analyte in the channel region of the device or changes to the Dirac point of the device, i.e., the relationship between current flowing between the source and drain electrodes, i.e., via the graphene layer of the device, and voltage applied to the top gate caused by the presence of target analyte in the channel region of the device.

In some embodiments, the device further comprises a cover layer configured to form an isolated microfluidic region over the graphene layer. In such embodiments, the cover layer may substantially cover the device such that a section of an exposed surface of the graphene layer present in the channel region remains uncovered. Such configuration of the cover of the device may form a microfluidic region, that is, a region configured to receive liquid that forms the liquid top gate, in which target analyte may be present. Such region may be further configured to enable liquid forming the liquid top gate to flow over the exposed graphene layer, i.e., as a flow cell or constituent part thereof, such that the graphene layer of the device may be exposed to a plurality of liquids forming the liquid top gate, such as liquids comprising a variety of concentrations of electrolyte or liquids comprising a biological sample or different concentrations thereof. In embodiments, the cover may be formed from any convenient material, such as, for example, materials capable of preventing covered regions of the device from exposure to the liquid top gate. In embodiments, the cover may be made from, for example, fabricated polydimethylsiloxane (PDMS) or similar materials.

### Surface Functionalization:

In embodiments of the device according to the present invention, the graphene layer comprises surface functionalization configured to enhance specificity of an analyte attracted to the graphene layer. As described above, the device may be configured so that application of dielectrophoretic (DEP) force by the device draws target analyte into the channel region in order to interact with an exposed surface of the graphene layer of the device. Whereas application of a dielectrophoretic (DEP) force may apply a force to analyte generally (e.g., analyte present in the liquid top gate), embodiments that include surface functionalization facilitate attracting specific analyte, i.e., target analyte, into the channel region of the device. In embodiments, attracting target analyte to the graphene layer of the device may cause target analyte, if any, to be attracted to, and to remain in, a location proximal to the graphene layer such that the target analyte causes changes in an electrical property of the device thereby enabling the device to evaluate the presence of target analyte in a biological sample included in the liquid top gate. In some embodiments, surface functionalization may repel analyte other than target analyte (i.e., other than the specific analyte the surface functionalization is intended to attract) such that electrical properties of the device change only upon the presence of target analyte in a biological sample present in the liquid top gate. That is, surface functionalization may be configured to interact with only a single, specific, type of analyte, i.e., target analyte. As described above, in embodiments, the analyte, i.e., the target analyte, is, e.g., a virus particle or virus protein or a fragment, such as the SARS-COV-2 spike protein or a fragment thereof.

Any convenient form of surface functionalization may be applied to embodiments of the device. In embodiments, surface functionalization comprises a probe for the analyte. For example, the graphene layer of the device may comprise a surface that is exposed to the channel region, and such surface may be configured to include one or more probes for the analyte. Probes may be disposed on the graphene layer in any convenient manner, for example, probes may be 3-D printed onto a surface of the graphene layer, and probes may be arranged in any convenient pattern, such as, substantially evenly distributed throughout a surface of the graphene layer or present primarily in positions proximal to edge regions where the graphene layer crosses a region of the bottom gate electrode.

To provide for stable attached of probes to the surface of the graphene layer, the graphene layer may be modified. For example, in some embodiments, I-pyrenebutyric acid N-hydroxysuccinimide ester (PBASE) is attached to the graphene surface. The pyrene end of the PBASE attaches to the graphene through p-p interactions, while the succinimide portion extends outward from the graphene enabling bonding to the probe, e.g., antibody or nucleic acids, such as described in greater detail below. In order to attach the probe, where desired the probe may be modified to include an amine group. This modified probe is exposed to the PBASE-covered graphene in solution and allowed to crosslink with the succinimide to form a stable functionalization layer. In general, the functionalization procedure is achieved by soaking the entire substrate in a probe-containing solution such as acetonitrile, though this process can readily be modified to achieve locally functionalized devices on the same chip using nozzle-based or 3D printing, thus enabling multiplexed sensing capability. Further details regarding graphene functionalization to enable stable probe attachment are provided in International Pub. No. WO 2012/145247 A1, the disclosure of which is herein incorporated by reference.

In embodiments, the probe may be configured to specifically bind to target analyte. That is, such that binding to target analyte is favored, e.g., energetically favored, over binding to other analyte (i.e., that differs from target analyte) present in the electrolyte solution of the top gate. The term “specific binding” refers to a direct association between two molecules, due to, for example, covalent, electrostatic, hydrophobic, and ionic and/or hydrogen-bond interactions, including interactions such as salt bridges and water bridges. A specific binding member describes a member of a pair of molecules which have binding specificity for one another. The members of a specific binding pair may be naturally derived or wholly or partially synthetically produced. One member of the pair of molecules has an area on its surface, or a cavity, which specifically binds to and is therefore complementary to a particular spatial and polar organization of the other member of the pair of molecules. Thus, the members of the pair have the property of binding specifically to each other. Examples of pairs of specific binding members are antigen-antibody, biotin-avidin, hormone-hormone receptor, receptor-ligand, enzyme-substrate. Specific binding members of a binding pair exhibit high affinity and binding specificity for binding with each other. Typically, affinity between the specific binding members of a pair is characterized by a K_{D} (dissociation constant) of 10⁻⁶ M or less, such as 10⁻⁷ M or less, including 10⁻⁸ M or less, e.g., 10⁻⁹ M or less, 10⁻¹⁰ M or less, 10⁻¹¹ M or less, 10⁻¹² M or less, 10⁻¹³ M or less, 10⁻¹⁴ M or less, including 10⁻¹⁵ M or less. “Affinity” refers to the strength of binding, increased binding affinity being correlated with a lower K_{D}. In an embodiment, affinity is determined by surface plasmon resonance (SPR), e.g., as used by Biacore systems. The affinity of one molecule for another molecule is determined by measuring the binding kinetics of the interaction, e.g., at 25° C. Examples of probes that can be used to bind to, and evaluate the presence of, an analyte as provided herein include, without limitation, antibodies, antigens, binding molecules, nucleic acids and aptamers.

In some cases, an antibody or antibody fragment can be used as a probe to evaluate the presence, absence or amount of a protein analyte within a sample being evaluated. For example, a monoclonal antibody, a polyclonal antibody, a bi-specific antibody, a single chain variable fragment (scFv), or an antigen-binding fragment of an antibody (e.g., Fab, Fab′, or F(ab′)₂) can be used to provide surface functionalization of a graphene layer of a device for evaluating the presence of an analyte (e.g., a protein analyte).

In some cases, a protein that binds to another molecule (e.g., another protein or chemical) can be used as a probe to evaluate the presence, absence or amount of an analyte within a sample being analyzed. For example, a protein antigen (e.g., muscle-specific kinase (MUSK)) can be used as a probe to detect the presence, absence or amount of an immunoglobulin that binds to that protein antigen (e.g., an anti-MUSK autoantibody). In some cases, the presence of anti-MUSK autoantibodies within a human sample can indicate that the human has myasthenia gravis.

In some cases, nucleic acid can be used as a probe to detect the presence, absence or amount of a nucleic acid analyte within a sample being analyzed. Any appropriate nucleic acid can be used as a probe to detect the presence, absence or amount of a nucleic acid analyte within a sample being analyzed. For example, DNA, RNA, and DNA/RNA hybrids can be used as a probe. In some cases, a nucleic acid analog (e.g., a peptide nucleic acid (PNA)) can be used as a probe to detect the presence, absence or amount of a nucleic acid analyte within a sample being analyzed. As described herein, a nucleic acid probe (or nucleic acid analog probe) can be designed to hybridize with a particular nucleic acid analyte. In some cases, a nucleic acid probe can be entirely single stranded or can contain at least one or more regions of single stranded nucleic acid, e.g., single stranded DNA (ssDNA). For example, a device or system described herein can include a graphene layer that has single-stranded nucleic acid attached, i.e., providing surface functionalization.

A nucleic acid probe described herein (or nucleic acid analog probe described herein) can be any appropriate length provided that the probe is capable of hybridizing to an analyte to be detected. For example, a nucleic acid probe can be from about 10 to about 500 or more nucleotides (e.g., from about 10 to about 400 nucleotides, from about 10 to about 300 nucleotides, from about 10 to about 200 nucleotides, from about 10 to about 100 nucleotides, from about 10 to about 50 nucleotides, from about 10 to about 25 nucleotides, from about 20 to about 500 nucleotides, from about 30 to about 500 nucleotides, from about 40 to about 500 nucleotides, from about 50 to about 500 nucleotides, from about 15 to about 50 nucleotides, from about 15 to about 25 nucleotides, from about 20 to about 50 nucleotides, or from about 18 to about 25 nucleotides) in length.

A nucleic acid probe described herein (or a nucleic acid analog probe described herein) can be designed such that any appropriate nucleic acid analyte can be detected using nucleic acid sequence databases such as GenBank®. For example, computer-based programs can be used to design particular nucleic acid probes that can bind to a portion of a nucleic acid analyte based on sequence hybridization.

Any appropriate method can be used to obtain a probe described herein. For example, molecular cloning techniques, chemical nucleic acid synthesis techniques, and/or chemical protein synthesis techniques can be used to obtain a nucleic acid and protein probes.

In some cases, embodiments of the devices provided here can be used to evaluate a sample for the presence of a coronavirus, such as SARS-COV-2. The SARS-COV-2 nucleocapsid protein is described in Dutta et al. (2020) Journal of Virology 94(13): e00647-20; Zeng et al. (2020) Biochem Biophys Res Commun. 527(3): 618-623; and Kang et al. (2020) Acta Pharmaceutica Sinica B 10(7): 1228-1238, the disclosures of which are incorporated herein by reference in their entireties. In some instances, the first and second binding members may be cross reactive with the SARS-COV nucleocapsid protein. The SARS-COV nucleocapsid protein and/or exemplary antigenic determinants of interest on a SARS-COV nucleocapsid protein are described in U.S. Pat. Nos. 7,696,330; 7,897,744; 7,696,330; 8,343,718; U.S. Publication No.'s: 20080269115; 20100172917; 20090280507; 20080254440; 20070128217, the disclosures of which are incorporated by reference herein in their entireties. In such instances, the first and second binding members may not be cross-reactive with other coronaviral nucleocapsid proteins, e.g., MERS-COV Nucleoprotein protein; HCOV-229E Nucleoprotein protein; HCoV-NL63 Nucleoprotein protein; HCoV-HKU1(isolate N5) Nucleoprotein protein; and HCoV-OC43 Nucleoprotein.

In some cases, embodiments of the devices provided herein can be used to evaluate a sample for the presence of an influenza virus. e.g., influenza A virus, influenza B virus, or influenza C virus, and combinations thereof.

In some cases, embodiments of devices provided herein can be used to evaluate a sample for the presence of Zika virus. For example, an embodiment of a bifunctional DEP-GFET device provided herein can include one or more graphene layers that includes a probe (e.g., an anti-NS1 antibody) that binds to NS1 polypeptides of a Zika virus. In some cases, a bifunctional DEP-GFET device provided herein can include one or more graphene layers having a surface that includes surface functionalization (e.g., a probe comprising single-stranded nucleic acid that hybridizes to NS1-encoding nucleic acid) that binds to Zika virus nucleic acid that encodes an NS1 polypeptide. Detection of one or more analytes of a Zika virus can indicate the presence of Zika virus in the mammal (e.g., human) from whom the sample was obtained.

In some cases, embodiments of devices provided herein can be used to assess a sample for the presence of HIV virus. For example, a bifunctional DEP-GFET device provided herein can include one or more graphene layers that includes surface functionalization (e.g., a probe comprising an anti-HIV antibody) that binds to a polypeptide of an HIV virus (e.g., a p24 antigen). In some cases, a bifunctional DEP-GFET device provided herein can include one or more graphene layers having a surface that includes surface functionalization (e.g., a probe comprising single-stranded nucleic acid that hybridizes to an HIV nucleic acid) that binds to HIV nucleic acid. Detection of one or more analytes of HIV can indicate the presence of HIV in the mammal (e.g., human) from whom the sample was obtained.

In embodiments, the probe is stably associated with a surface of the graphene layer. That is, in embodiments, the probe is associated with the graphene layer such that the probe remains associated with the graphene layer upon introduction of liquid forming the liquid top gate as well as upon the probe binding with analyte, if any, present in a sample added to liquid top gate. Any convenient form of stably associating a probe with the graphene layer may be applied, as such are known in the art. For example, the stable association may comprise a covalent bond. In other embodiments, the stable association may comprise other binding techniques, including, but not limited to, for example, ionic bonding, pi-pi binding, sigma binding, polar bonding or electrostatic bonding. In embodiments, surface functionalization may comprise amine-reactive crosslinker reactive groups, such as amine-esters.

In some embodiments, surface functionalization further comprises a second probe for a second analyte. That is, in some cases, the device may be configured to evaluate the presence of one or two target analytes. In such embodiments, a surface of the graphene layer exposed to the channel region of the device may comprise probes for each of two different target analytes or, in other cases, for two different features of the same analyte.

### Array of Devices:

In embodiments, the device comprises two or more distinguishable subunits, each comprising a DEP component and a GFET component, wherein the subunits are independently operable. In each subunit, the DEP component and the GFET component may be substantially the same or may differ, such as, for example, comprising different surface functionalization on their respective graphene layers. That is, the subunits may comprise surface functionalization configured to attract different analytes to different subunits. In this context, by “independently operable,” it is meant that each subunit is capable of applying a DEP force with the DEP component separately and independently from the other submit as well as capable of operating each GFET component, e.g., to detect a change in an electrical property of the respective subunit, separately and independently from the other subunit. In embodiments, the device may comprise an array of subunits, such as one, two, three, four, five, six, seven, eight, nine, ten, 11, 12, 16, 64, 128, 192, 256, 512 or more subunits.

Embodiments may, for example, be configured to evaluate the presence of multiple different target analytes, i.e., one analyte per subunit. Such embodiments may be configured to evaluate the presence of more than one analyte in a biological sample. In some cases, subunits of the system may form separate and independent biosensors configured to sense the same analyte, for example, by sensing the same features or different features of the analyte (i.e., include different surface functionalization, each configured to specifically bind to different regions of the same analyte). Such embodiments are configured to provide a redundant technique for evaluating the presence of an analyte in a biological sample.

In some cases, the two or more subunits are supported on a common substrate. That is, in such embodiments, a single chip may be configured to evaluate the presence of more than one analyte, i.e., one analyte per subunit, where the plurality of subunits is present on a common substrate.

In embodiments of the device according to the invention that comprise two or more distinguishable subunits, as described above, the device may further comprise a cover layer configured to form isolated microfluidic regions over each subunit. The cover layer, similar to that described above, may be configured to allow fluid that forms the liquid top gate of each subunit of the device to be isolated over each graphene layer of the subunits. In such embodiments, the cover layer may be configured such that the liquid top gate of one subunit is not in fluidic communication with the liquid top gate of any other subunit of the device. In embodiments, the isolated microfluidic regions may be microfluidic wells. In some embodiments, the isolated microfluidic regions are configured to expose graphene layers of the subunits to the well, i.e., to the liquid top gate. That is, the device may include a cover shaped to form wells over the graphene layer of each subunit of the device thereby facilitating the independent operation of each subunit of the device, i.e., so that the liquid present over each subunit forms a top gate capable of independent operation from the top gate of any other subunit.

In some cases, each isolated microfluidic region is associated with at least two subunits. That is, each microfluidic region may form a single well configured to receive fluid, in which at least two subunits are exposed to the fluid present in each well. In embodiments, each subunit of a single microfluidic region may be configured substantially the same, e.g., include features such as surface functionalization designed to attract the same analyte. Such a configuration would provide at least one redundant subunit in the event of subunit failure. Further, in embodiments, the subunits of one microfluidic region may be configured differently from the subunits of a different microfluidic region, e.g., may include features such as surface functionalization designed to attract different analyte, such that each microfluidic region is configured to attract, and evaluate the presence of, different analyte.

In other embodiments, the device is a component of a multiplex analyte sensing chip. That is, the device is configured to sense the presence of a plurality of different analyte and separately (i.e., via multiplexing results of evaluating the presence of different analyte) indicate the presence of each different analyte.

### Systems With a Device and Voltage Source:

Aspects of the present disclosure include systems comprising a bifunctional graphene dielectrophoresis (DEP)-graphene field effect transistor (GFET) device, the device comprising: a graphene dielectrophoresis (DEP) component, and a graphene field effect transistor (GFET) component, wherein the graphene DEP and GFET components are independently operable, and a voltage source configured to output a plurality of independent voltages and operably connected to the device. That is, systems according to the present invention include a device, such as those described herein, with a voltage source operably connected to the device. Any convenient voltage source capable of generating a plurality of voltage potentials, as such are known in the art, for application to a bifunctional graphene dielectrophoresis (DEP)-graphene field effect transistor (GFET) device according to the present invention may be applied. Voltage sources of interest include battery-powered voltage sources, including, for example re-chargeable battery-powered voltage sources, connections to external power sources, e.g., via a plug-in adaptor such as a universal serial bus adaptor or the like, or a solar power voltage source. Voltage sources of interest may further include voltage sources capable of generating a range of different voltage potentials under the control of a controller, including, for example, AC and/or DC voltage potentials. In some cases, the voltage source may comprise a plurality of independently operable voltage sources, where each independently operable voltage source is configured to be applicable to different electrodes of the device. In embodiments, the voltage source is configured such that it is capable of applying voltages sequentially. For example, the voltage source may be configured to: (1) first apply one or more voltage biases to cause the device to apply a DEP force (i.e., first applying voltage to the bottom gate electrode), (2) followed by turning off voltage biases causing the device to apply a DEP force (i.e., followed by turning off voltage to the bottom gate electrode), (3) followed by turning on voltage biases to either the source or the drain, and, (4) finally, turning on one or more voltage biases to cause the device to apply a DEP force again. The voltage source may be configured to apply other combinations of voltage biases, including sequential combinations of voltage biases, as desired. Voltage sources of interest are configured to supply either or both of positive and negative voltages; voltages specified throughout this description may be specified as positive voltages as a matter of convenience only, as such voltages refer to absolute values of voltages, i.e., to voltage magnitude only, not polarity, such that embodiments of the invention are not limited to applying only positive voltage polarities.

### Bottom Gate Bias for Dep Functionality:

In embodiments of systems according to the present invention, the voltage source is configured to apply a bottom gate bias (V_{BG}) to the bottom gate electrode of the bifunctional graphene dielectrophoresis (DEP)-graphene field effect transistor (GFET) device. Any convenient voltage for the bottom gate bias (V_{BG}) may be applied. In embodiments, the bottom gate bias (V_{BG}) is an AC bias with a specified frequency (v) and peak-to-peak voltage (V_{PP}). In embodiments, the bottom gate bias (V_{BG}) may range from 0.1 to 20 Volts, including for example from 0.5 to 5 Volts or 1 to 3 Volts, where such voltage ranges refer to peak-to-peak voltages (V_{PP}) of an AC bias. As used here and throughout this description, voltages specified as positive voltages refer to absolute values of voltages, i.e., to voltage magnitude only, not polarity, such that the disclosure is not limited to applying only positive voltage polarities. Any convenient specified frequency (v) for the bottom gate bias (V_{BG}) may be applied and such may range from 100 Hz to 50 MHz, including for example from 10 kHz to 10 MHz or 500 kHz to 5 MHz or 800 kHz to 8 MHz. In some cases, as described below, it may be desired to cause the drain bias (V_{D}) to be 0 Volts, e.g., while a bottom gate bias (V_{BG}) is applied to cause the device to apply a DEP force.

As described in detail below, in embodiments, independent operation of the bottom gate electrode facilitates independent operation of the DEP component of the device. That is, application of a bottom gate bias (V_{BG}) with an AC bias characterized by a specified frequency (v) and peak-to-peak voltage (V_{PP}) may cause the DEP component to apply a dielectrophoretic (DEP) force, such as either a positive force attracting analyte to the device or a negative force repelling analyte away from the device. The nature of the DEP force applied by the device may vary based on the specified frequency (v) and peak-to-peak voltage (V_{PP}) applied as a bottom gate bias (V_{BG}). In embodiments, the voltage source is configured to apply a bottom gate bias (V_{BG}) to the bottom gate electrode with a range of frequencies (v) and peak-to-peak voltages (V_{PP}), for example, under the control of a controller.

### Drain and Top Gate Biases for GFET Functionality:

In embodiments of systems according to the present invention, the voltage source is configured to apply a drain bias (V_{D}) to the drain electrode of the bifunctional graphene dielectrophoresis (DEP)-graphene field effect transistor (GFET) device. In embodiments, the drain bias (V_{D}) is a DC bias. Any convenient voltage for the drain bias (V_{D}) may be applied and such may range from 0 to 10 Volts, including for example from 0.1 to 1 Volts or 0.1 to 5 Volts.

In some cases, it may be desired to cause the drain voltage to be 0 Volts, e.g., while the device is applying a DEP force. In embodiments, the voltage source is configured to apply a drain bias (V_{D}) to the drain electrode with a range of voltages, for example, under the control of a controller. In some embodiments, the source electrode of the bifunctional graphene dielectrophoresis (DEP)-graphene field effect transistor (GFET) device is connected to ground. That is, the source electrode may act as a reference voltage from which voltages applied to other electrodes of the device are distinguished.

In embodiments of systems according to the present invention, the voltage source is configured to apply a top gate bias (V_{TG}) to the top gate electrode of the bifunctional graphene dielectrophoresis (DEP)-graphene field effect transistor (GFET) device. In some embodiments, the top gate bias (V_{TG}) is a DC bias. That is, the top gate bias (V_{TG}) gate may comprise a constant voltage potential applied to the top gate. Any convenient voltage for the DC bias of the top gate bias (V_{TG}) may be applied and such may range from 0 to 5 Volts, including for example from 0 to 1 Volts or 0 to 2 Volts or 0 to 3 Volts or 0 to 4 Volts or 0 to 5 Volts or 1 to 2 Volts or 2 to 3 Volts or 3 to 4 Volts or 4 to 5 Volts. In embodiments, the voltage source is configured to apply a top gate bias (V_{TG}) to the top gate electrode with a range of voltages, for example, under the control of a controller.

In other embodiments, the top gate bias (V_{TG}) comprises a voltage sweep. That is, the top gate bias (V_{TG}) comprises applying a range of voltages applied over a specified period time, where such range of voltages may be applied periodically. Any convenient range of voltages for the top gate bias (V_{TG}) may be applied and such may range from −5 to +5 Volts, including for example from −5 to 0 Volts or −2 to 2 Volts or 0 to 1 Volts or 0 to 5 Volts. For example, the voltage sweep of the top gate bias (V_{TG}) may comprise a saw-tooth pattern of voltages, where in one period such saw-tooth pattern of the top gate bias (V_{TG}) voltage spans a minimum and maximum voltage with a constant rate of change of voltage over a specified period of time. In such embodiments, the top gate bias (V_{TG}) voltage sweep spans a Dirac voltage of the device. That is, the range of voltages applied to the top gate as part of the top gate bias (V_{TG}) voltage sweep includes a top gate bias (V_{TG}) voltage at which the magnitude of the current through the drain of the device is expected to be minimal. As described above, such Dirac voltage of the device may change as a result of the interaction between the graphene layer of the device and analyte (i.e., target analyte present in a biological sample included in the liquid top gate). In embodiments, the voltage source is configured to apply a top gate bias (V_{TG}) to the top gate electrode with a voltage sweep over a range of voltages, i.e., a range of minimum and maximum voltages and periods of the voltage sweep, for example, under the control of a controller.

### Systems With a Sensor for Measuring Electrical Changes of the Device:

Embodiments of systems according to the present invention may further comprise a sensor operably connected to the device and configured to sense an electrical characteristic of the device. As described above, under certain circumstances, electrical characteristics of the device, such as, e.g., the magnitude of current via the drain of the device or the Dirac point of the device, may change based on, for example, the interaction between analyte present in the liquid top gate and the graphene layer of the device. Any convenient sensor may be applied, and such sensor may vary depending on the configuration and/or application of the device. In some embodiments, the sensor comprises a circuit configured to sense an electrical characteristic of the device. In certain cases, the sensor is embedded within the device. By embedded within the device, it is meant that the sensor is present on the substrate of the device, such that the substrate forms a common substrate between the device and the sensor. In some cases, the circuit being embedded within the device comprises the circuit being integrated into the device. For example, the circuit may comprise a current-sensing circuit wired in series with an electrode of the device such that the electrode of the device comprises the sensor.

In embodiments, the sensor is configured to sense current flowing between features of the device. In some embodiments, the sensor is configured to sense current between the source electrode and the drain electrode. That is, the circuit is a current-sensing circuit, i.e., a circuit that functions as, or substantially similar to, an ammeter, with respect to drain current (I_{D}). In other embodiments, the sensor is configured to sense a voltage differential between features of the device. In some embodiments, the sensor is configured to sense voltage between the source electrode and the drain electrode. That is, the circuit is a voltage-sensing circuit, i.e., a circuit that functions as, or substantially similar to, a voltmeter, with respect to a voltage differential between the drain electrode and the source electrode.

### Systems With Controller:

Embodiments of systems according to the present invention may further comprise a controller operably connected to the sensor and configured to detect a change in an electrical characteristic of the device sensed by the sensor. Any convenient controller may be applied, as such are known in the art. In some cases, the controller comprises a hardware controller or a microcontroller that is a combination of a hardware and software controller. In some cases, the controller comprises an application specific integrated circuit (ASIC) or a field-programmable gate array (FPGA) or the like. In some cases, the controller is configured to detect that a sensor has sensed a change in an electrical characteristic of the device and further controls the voltage source, i.e., controls the voltage potentials applied to one or more of the bottom gate electrode, the drain electrode or the top electrode.

### Systems With Transmitters:

Embodiments of systems according to the present invention may further comprise a transmitter configured to transmit an output of the sensor. In embodiments, such transmitter may be further configured to transmit an output of the controller. In other embodiments, the system may comprise an additional transmitter configured to transmit an output of the controller. That is, the transmitter may be configured to transmit information collected by the device regarding the presence of analyte in a sample and/or characteristics of the device. Any convenient transmitter may be applied as such are known in the art. In embodiments, the transmitter is a wireless transmitter. In embodiments, the system is configured to comprise a transmitter configured to transmit information as to whether the analyte is present in a sample over a network (e.g., LAN, WAN, wireless network, wired network, internet, VPN, mobile data network, cellular network, BLUETOOTH network, and/or combinations thereof) to a server system (e.g., cloud-based server) and/or another electronic device (e.g., smartphone, laptop computer or desktop computer). For example, a transmitter may comprise a wireless communication transmitter (e.g., a radio transmitter such as a BLUETOOTH transmitter, a Wi-Fi transmitter, a near field communication (NFC) transmitter, a mobile data network (e.g., 5G network, 4G network, LTE network) transmitter) and can transmit information over a network (e.g., LAN, WAN, wireless network, wired network, internet, VPN, mobile data network, cellular network, BLUETOOTH network, and/or combinations thereof) to a server system (e.g., cloud-based server) and/or another electronic device (e.g., a user's smart phone).

### System With Multiple Devices:

Embodiments of systems according to the present invention may be configured such that the device comprises two or more distinguishable subunits, each comprising a DEP component and a GFET component, wherein the subunits are independently operable and wherein the voltage source is operably connected to each of the subunits. That is, the system may be configured such that that device comprises an array of subunits, as described above and the voltage source is configured to independently apply bias voltages to the different electrodes of each subunit. In embodiments, the system may comprise an array of subunits, such as one, two, three, four, five, six, seven, eight, nine, ten, 11, 12, 16, 64, 128, 192, 256, 512 or more subunits.

In embodiments, each of the subunits of the system may form a separate and independent biosensor device configured to sense different analyte (i.e., different target analyte). Such embodiments are configured to evaluate the presence of more than one analyte in a biological sample. In some cases, subunits of the system may form a separate and independent biosensor configured to sense the same analyte. For example, different subunits configured to evaluate the presence of the same features of the analyte or different features of the analyte (i.e., include different surface functionalization, each configured to specifically bind to different regions of the same analyte). Such embodiments are configured to provide a redundant technique for evaluating the presence of an analyte in a biological sample. In some cases, systems comprising a plurality of subunits comprise a multiplex analyte sensing chip, as described above.

Various aspects of the devices and systems of the invention being generally described above, elements of the devices and systems are now further reviewed in the context of specific embodiments.

### EXEMPLARY EMBODIMENTS

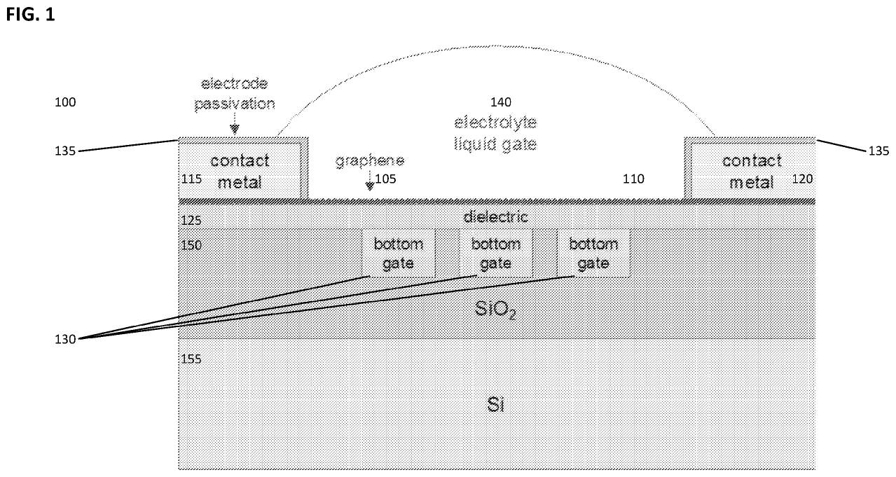

Aspects of the claimed invention are described in connection with embodiments of the device depicted in FIGS. 1-4 for ease of illustration only and without limiting the present invention to such embodiments.

### Bifunctional DEP-GFET Device:

FIG. 1 provides a cross-sectional view of a DEP-GFET device 100 according to an embodiment of the invention. In connection with referring to FIG. 1, “top” refers to the top of the figure and an upper, or higher, surface of DEP-GFET device 100, and “bottom” refers to the bottom of the figure and a bottom, or lower, surface of DEP-GFET device 100. On device 100, graphene layer 105 is present in channel region 110. Channel region 110 is defined as the space present between source 115 and drain 120 electrodes. Each of source 115 and drain 120 electrodes are electrically isolated from one another but are electrically connected to graphene layer 105 on either side of channel region 110.

Graphene layer 105 is disposed on top of dielectric layer 125, which spans the width of channel region 110 and source 115 and drain 120 electrodes. Dielectric layer 125 comprises an electrical insulator, such as an insulator with a dielectric constant greater than four, that separates, and electrically isolates, graphene layer 125 from bottom gate electrode 130. Bottom gate electrode 130 is present beneath channel region 110 and is arranged such that multiple, electrically interconnected, “fingers” of bottom gate electrode 130 span channel region 110. That is, bottom gate electrode 130 is arranged in an interdigitated fashion beneath channel region 110. Such arrangement increases the number of instances that bottom gate 130 crosses below graphene layer 105, each crossing forming an edge.

As described above, bottom gate 130 is electrically isolated from graphene layer 105 by dielectric layer 125. Bottom gate 130 is also electrically isolated from source 115 and drain 120 electrodes. Bottom gate electrode 130 is positioned between source 115 and drain 120 electrodes. That is, source 115 and drain 120 electrodes are electrically connected to graphene layer 110 on either side of the bottom gate electrode 130.

Electrode passivation layer 135 is disposed on top of source 115 and drain 120 electrodes. Electrode passivation layer 135 is deposited as a layer on top of source 115 and drain 120 electrodes and is seen on both the left-hand and right-hand sides of device 100. Electrode passivation layer 135 comprises an electrical insulator and is configured to minimize leakage from source 115 and drain 120 electrodes.

Channel region 110 is configured to receive an electrolyte solution that functions as an electrolyte liquid top gate 140 of device 100. The electrolyte solution that functions as electrolyte liquid top gate 140 is present on either side of source 115 and drain 120 electrodes and in contact with a surface of graphene layer 105. The electrolyte solution that functions as electrolyte liquid top gate 140 is depicted as a section of an ellipse present on the top of device 100 (i.e., a liquid droplet present on top of device 100). Electrode passivation layer 135 electrically isolates source 115 and drain 120 electrodes from electrolyte liquid top gate 140 minimizing leakage from electrolyte liquid top gate 140 through source 115 or drain 120 electrodes. When device 100 is deployed to attract and/or evaluate the presence of an analyte in a sample, the electrolyte solution comprising electrolyte liquid top gate 140 may include a sample, such as a biological sample, in which analyte may or may not be present.

Dielectric layer 125 is disposed on top of silicon oxide layer 150. Silicon oxide layer 150 is configured so that bottom gate electrode 130 is embedded within silicon oxide layer 150 such that bottom gate electrode is present near the top of silicon oxide layer 150. In embodiment 100, bottom gate electrode 130 is in contact with the bottom surface of dielectric layer 125.

Silicon oxide layer 150 spans the width of device 100. Silicon substrate 155 is present below silicon oxide layer 150 and, along with silicon oxide layer 150, acts as a substrate supporting the components described above. That is, silicon substrate 155, along with silicon oxide layer 150, supports the DEP component and the GFET component and their constituent components.

While in embodiment of GFET-DEP device 100, a silicon oxide layer 150 and silicon layer 155 together form a substrate of device 100, it need not always be the case that a substrate is formed from two layers or from either or both of Silicon or Silicon Oxide.

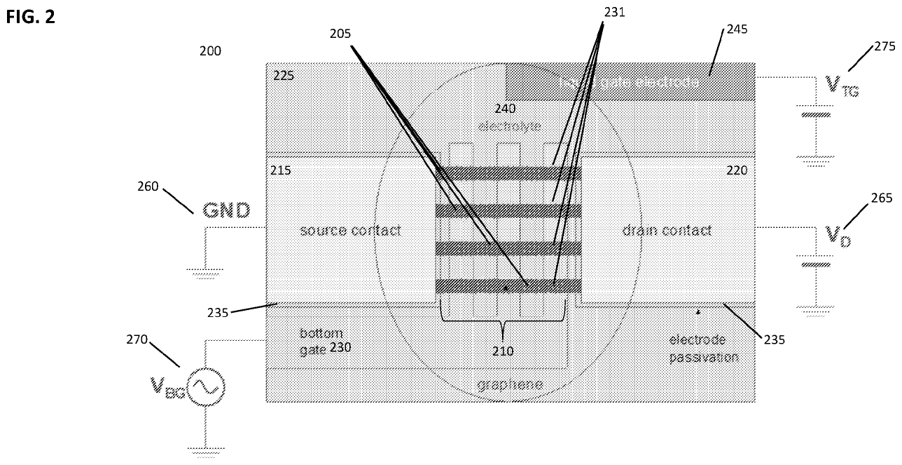

FIG. 2 provides a top view of DEP-GFET device 200 according to an embodiment of the invention. That is FIG. 2 is “looking down” on DEP-GFET device 200 such that the “top” of device 200 is a layer closest to the viewer of FIG. 2, and the “bottom” of device 200 is a layer furthest from the viewer of FIG. 2. The right and left sides of device 200 depicted in FIG. 2 correspond to the right and left sides of device 100 depicted in FIG. 1.

On device 200, graphene layer 205 is present in channel region 210. Graphene layer 205 is configured as a series of four parallel strips of graphene that extend laterally across channel region 210. Channel region 210 is defined as the space present between source 215 and drain 220 electrodes. Each of source 215 and drain 220 electrodes are electrically isolated from one another but are electrically connected to graphene layer 205 on either side of channel region 210, i.e., each of the four strips of graphene layer 205 depicted crossing channel region 210 are electrically connected to both source electrode 215 and drain electrode 220.

Graphene layer 205 is disposed on top of dielectric layer 225. Dielectric layer 225 is present throughout device 200, including spanning the width of channel region 210 between source 215 and drain 220 electrodes. Dielectric layer 225 comprises an electrical insulator, such as one with a dielectric constant greater than four, that separates, and electrically isolates, graphene layer 225 from bottom gate electrode 230. Dielectric layer 225 is depicted in FIG. 2 in a “see-through” manner such that the configuration of bottom gate electrode 230 is shown, notwithstanding that dielectric layer 225 covers bottom gate electrode 230 (consistent with the depiction of bottom gate electrode 130 as being “below” dielectric layer 125 in FIG. 1). Bottom gate electrode 230 is present beneath channel region 210 and is arranged such that multiple, electrically interconnected, “fingers” of bottom gate electrode 230 span channel region 210.

That is, bottom gate electrode 230 is arranged in an interdigitated fashion beneath channel region 210. The “fingers” of bottom gate electrode 230 are shown vertically spanning channel region 210 in FIG. 2, where each “finger” is electrically connected with each other via horizontal member of bottom gate electrode 230 depicted towards the bottom of FIG. 2. In contrast, bottom gate electrode 230 is electrically isolated from graphene layer 205, as they are separated by dielectric layer 225.

Such arrangement, where bottom gate electrode 230 includes multiple “fingers” and graphene layer 205 includes multiple parallel strips of graphene spanning channel region 210, increases the number of instances that bottom gate 230 crosses beneath graphene layer 205. Each such crossing forms an edge, for example, edges 231, seen on the right side of channel region 210. When appropriate voltages are applied to constituent elements of device 200, each such edge, including edges 231, produces a dielectrophoretic force for trapping analyte.

Therefore, the number and configuration of edges, such as edges 231, effects the characteristics and functionality of the DEP component of device 200, including for example, the amount of force applied by the DEP component to attract (or repel) molecules, including analyte, into channel region 210.

As described above, bottom gate 230 is electrically isolated from graphene layer 205 by dielectric layer 225. Bottom gate 230 is also electrically isolated from source 215 and drain 220 electrodes. In contrast, source 215 and drain 220 electrodes are electrically connected to graphene layer 210 on either side of bottom gate electrode 230 in channel region 210.

Electrode passivation layer 235 is disposed on source 215 and drain 220 electrodes such that electrode passivation layer 235 covers source 215 and drain 220 electrodes, including the top and sides of source 215 and drain 220 electrodes. Electrode passivation layer 235 comprises an electrical insulator and is configured to minimize leakage from source 215 and drain 220 electrodes.

Channel region 210 is configured to receive an electrolyte solution that functions as an electrolyte liquid top gate 240 of device 200. The electrolyte solution that functions as electrolyte liquid top gate 240 is present between either side of source 215 and drain 220 electrodes and is in contact with a top surface of graphene layer 205 present in channel region 210. In FIG. 2, the electrolyte solution that functions as electrolyte liquid top gate 240 is depicted as an ellipse (i.e., a droplet of liquid, e.g., sample) encompassing the entirety of channel region 210 as well as portions of source 215 and drain 220 electrodes. Electrode passivation layer 235, as described above, electrically isolates source 215 and drain 220 electrodes from electrolyte liquid top gate 240, notwithstanding that the electrolyte solution that functions as electrolyte liquid top gate 240 contacts both source 215 and drain 220 electrodes, minimizing leakage from electrolyte liquid top gate 240 through source 215 or drain 220 electrodes. When device 200 is deployed to attract and/or evaluate the presence of an analyte in a sample, the electrolyte solution comprising electrolyte liquid top gate 240 may include a sample, such as a biological sample, in which analyte may or may not be present.

The electrolyte solution that functions as electrolyte liquid top gate 240 of device 200 is electrically connected to top gate electrode 245 (i.e., liquid gate electrode). Top gate electrode 245 is depicted as present in the upper right corner of device 200. The electrolyte solution that functions as electrolyte liquid top gate 240 is shown as partly covering top gate electrode 245, such that the electrolyte solution of electrolyte liquid top gate 240 and top gate electrode 245 are electrically interconnected. Top gate electrode 245 is electrically isolated from source 215 and drain 220 electrodes, bottom gate 230 as well as graphene layer 205. Top gate electrode 245 and electrolyte liquid top gate 240 are configured such that an electrical potential applied to top gate electrode 245 influences electrolyte liquid top gate 240, including the volume of electrolyte liquid top gate 240 present in channel region 210.

A substrate layer, on which the components of device 200 are disposed is not depicted in FIG. 2. Such a substrate may comprise a layer, such as Silicon Oxide layer 150 and/or Silicon layer 155 of device 100 depicted in FIG. 1, present beneath dielectric layer 225 of device 200.

Also depicted in FIG. 2 are various voltages applied to each of the source 215 and drain 220 electrodes, bottom gate 230 as well as top gate electrode 245. Such voltages may be applied by one or more voltage sources (not shown). In some cases, such voltages may be applied by a single voltage source configured to produce a plurality of independent voltages or from a plurality of independent voltage sources, each configured to produce one or more voltages.

In FIG. 2, source 215 electrode is shown electrically connected to ground 260 such that source 215 of device 200 is grounded.

Drain 220 electrode is shown connected to VD 265, a DC bias, such that the electrical potential of drain 220 of device 200 differs from that of source 215 electrode by a constant, i.e., DC, voltage potential.

Bottom gate electrode 230 is shown connected to V_{BG} 270, an AC bias. The AC bias of V_{BG} 270 is characterized by a frequency (v) and a peak-to-peak voltage (V_{PP}). The voltage source supplying the AC bias of V_{BG} 270 has control over both such characteristics, frequency (v) and peak-to-peak voltage (V_{PP}) of V_{BG} 270. Frequency (v) of the AC bias of V_{BG} 270 refers to the oscillation frequency of the cyclical voltage changes that comprise the AC bias of V_{BG} 270. Peak-to-peak voltage (V_{PP}) refers to the magnitude of difference in voltage between the lowest and highest voltages of the AC bias of V_{BG} 270.

Top gate electrode 245 is shown connected to V_{TG} 275, a DC bias, such that the electrical potential of top gate electrode 245, and therefore the electrical potential of electrolyte liquid top gate 240, of device 200 differs from that of source 215 electrode by a constant, i.e., DC, voltage potential. The DC bias applied to V_{TG} 275 may differ from the DC bias applied to V_{D} 265 described above.

Independent operation of the voltage potentials, V_{D} 265, V_{BG} 270 and V_{TG} 275 (while source electrode 260 is electrically connected to ground) (i.e., independent application of voltage potentials to one or more of V_{D} 265, V_{BG} 270 and V_{TG} 275) facilitates independent operation of the DEP component and the GFET component of device 200. As such, device 200 can be operated in three regimes, including a DEP only regime (i.e., for applying a dielectrophoretic force in or near channel region 210), a GFET only regime (i.e., for evaluating a sample for the presence of an analyte present in or near channel region 210), and a DEP-GFET combined regime (i.e., for evaluating a sample for the presence of an analyte while simultaneously applying a dielectrophoretic force, such as to attract analyte to channel region 210 of device 200). Device 200 can therefore be operated differently depending on a desired specific application.

To operate device 200 in a DEP only regime requires applying an AC bias of V_{BG} 270 to bottom gate 230. To operate device 200 in the GFET only regime requires applying a DC bias of V_{D} 265 to drain 220 electrode and applying a DC bias of V_{TG} 275 to top gate electrode 245 (and therefore concurrently to electrolyte liquid top gate 240). To operate device 200 in the GFET-DEP combined regime requires applying an AC bias of V_{BG} 270 and simultaneously applying a DC bias of V_{D} 265 and a DC bias of V_{TG} 275.

### Bifunctional DEP-GFET Device With Surface Functionalization:

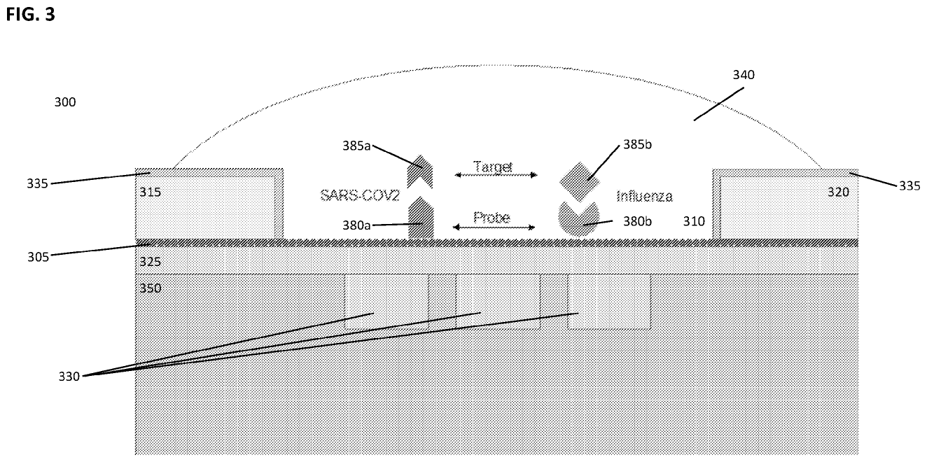

FIG. 3 provides a cross-sectional view of a DEP-GFET device 300 according to an embodiment of the invention, highlighting aspects of device 300 configured to attract analyte with specificity. Device 300 is similar to device 100 depicted in FIG. 1, such that components and configurations that are common in each of device 300 and device 100 are not described in further detail here.

In connection with referring to FIG. 3, “top” refers to the top of the figure and an upper, or higher, surface of DEP-GFET device 300, and “bottom” refers to the bottom of the figure and a bottom, or lower, surface of DEP-GFET device 300.

On device 300, graphene layer 305 is present in channel region 310. Channel region 310 is defined as the space present between source 315 and drain 320 electrodes.

Graphene layer 305 is disposed on top of dielectric layer 325, which spans the width of channel region 310 and source 315 and drain 320 electrodes. Dielectric layer 325 is disposed on top of substrate layer 350 configured to support the various components that make up device 300. Bottom gate electrode 330 is present beneath channel region 310 and is arranged such that multiple, electrically interconnected, “fingers” of bottom gate electrode 330 span channel region 310. Bottom gate electrode 330 is positioned between source 315 and drain 320 electrodes. Electrode passivation layer 335 is disposed on top of source 315 and drain 320 electrodes.

Channel region 310 is configured to receive an electrolyte solution that functions as an electrolyte liquid top gate 340 of device 300. The electrolyte solution that functions as electrolyte liquid top gate 340 is present on either side of source 315 and drain 320 electrodes and in contact with a surface of graphene layer 305. The electrolyte solution that functions as electrolyte liquid top gate 340 is depicted as a section of an ellipse present on the top of device 300 (i.e., a liquid droplet present on top of device 300).

When device 300 is deployed to attract and/or evaluate the presence of an analyte in a sample, the electrolyte solution comprising electrolyte liquid top gate 340 may include a sample, such as a biological sample, in which analyte may or may not be present. In FIG. 3, analyte is present in the electrolyte solution that comprises electrolyte liquid top gate 340, and abstract representations of two different target analytes are depicted within the electrolyte solution that comprises electrolyte liquid top gate 340. First target analyte 385a is a SARS-COV-2 target analyte, such as for example, a fragment of a SARS-COV-2 virus, such as a spike protein, or the like, and second target analyte 385b is an influenza analyte, such as for example, a fragment of an influenza virus or the like. First and second target analytes 385a 385b are referred to in the diagram as targets. While FIG. 3 depicts only one of each target analyte 385a 385b, more than one of each target analyte may be present in a biological sample included in electrolyte solution comprising electrolyte liquid top gate 340.

Channel region 310 includes surface functionalization. Specifically, channel region 310 includes first probe 380a configured to specifically bind to first target analyte 385a. For example, first probe 380a may be an antibody, or binding fragment thereof, or a protein or a nucleic acid, such as single stranded DNA. Because first probe 380a is configured to specifically bind with first target analyte 385a, which is related to a SARS-COV-2 virus, first probe 380a may be referred to as a SARS-COV-2 probe.

Channel region 310 also includes second probe 380b configured to specifically bind to second target analyte 385b. For example, second probe 380b may be an antibody, or binding fragment thereof, or a protein or a nucleic acid, such as single stranded DNA. Because second probe 380b is configured to specifically bind to second target analyte 385b, which is related to an influenza virus, second probe 380b may be referred to as an influenza probe.

Channel region 310 is depicted as including only one each of first and second probes 380a 380b. However, in embodiments, channel region 310 may include a plurality of probes targeting a single type of analyte or a plurality of types of analytes. First and second probes 380a and 380b are stably associated with graphene layer 305 or channel region 310 such that first and second probes 380a and 380b remain in a fixed position within channel region 310 even after binding with first and second target analyte 385a 385b, respectively.

Upon operation of device 300, application of electrical potentials to different electrodes results in generation of a dielectrophoretic force for attracting analyte to channel region 310. First and second probes 380a 380b also attract analyte to channel region 310, and, in the case of first and second probes 380a 380b, attract analyte with specificity. That is, whereas application of a dielectrophoretic force to the channel region attracts analyte generally, the configuration of first and second probes 380a 380b causes specific analyte to be attracted to and bond to and therefore remain present within channel region 310. Upon further operation of device 300, application of electrical potentials to different electrodes results in enabling device 300 to evaluate the presence of an analyte in a sample included in the electrolyte solution that comprises electrolyte liquid top gate 340. The combination of (i) operating device 300 to generate a dielectrophoretic force for attracting analyte to channel region 310 with (ii) surface functionalization in the form of, for example, first or second probes 380a 380b, for attracting specific analyte, such as first target analyte 385a or second target analyte 385b, to channel region 310, work together to enable device 300 to attract and subsequently evaluate the presence of analyte in a biological sample with a high degree of specificity. That is, application of such features enables device 300 to evaluate the presence of specific analyte (such as first target analyte 385a or second target analyte 385b) and not merely analyte generally. Specifically, in the event that, upon operation of device 300 to evaluate a sample for the presence of an analyte, device 300 indicates that analyte is present, the surface functionalization of graphene layer 305 in channel region 310 of device 300, indicates that a specific analyte is present in a biological sample present in the electrolyte solution that comprises electrolyte liquid top gate 340.

### Array of Bifunctional DEP-GFET Devices for Multiple Target Analyte Sensing:

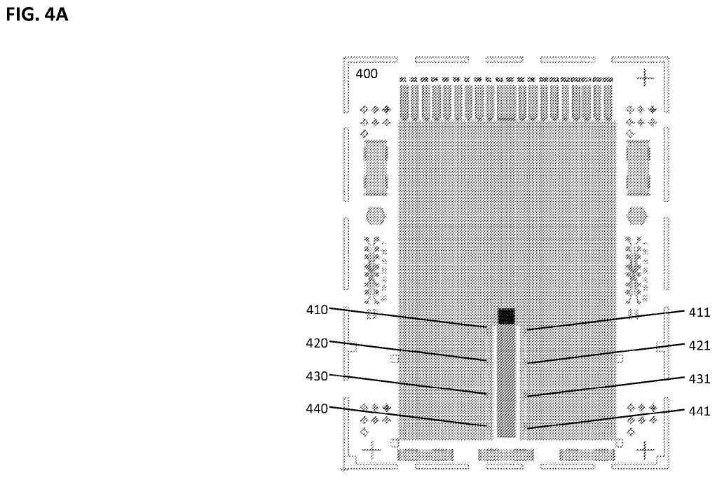

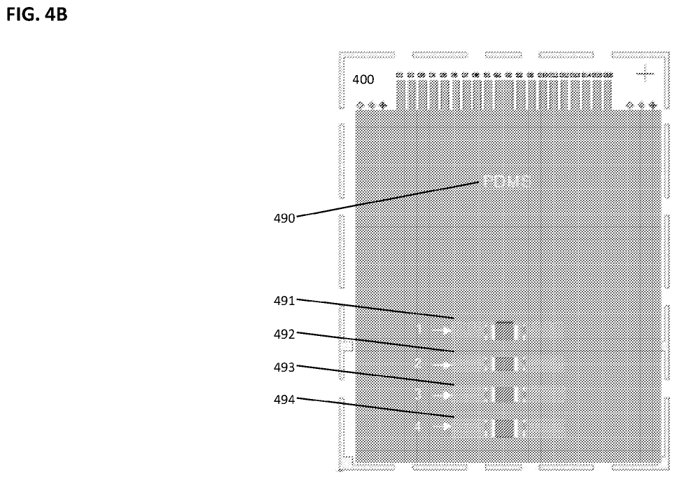

FIGS. 4A and 4B provide top views of DEP-GFET device chip 400 according to an embodiment of the invention. That is FIG. 4 is “looking down” on DEP-GFET device chip 400 such that the “top” of chip 400 is a layer closest to the viewer of FIGS. 4A and 4B, and the “bottom” of device 400 is a layer furthest from the viewer of FIGS. 4A and 4B.

FIG. 4A depicts DEP-GFET device chip 400 without cover 490. FIG. 4B depicts DEP-GFET device chip 400 with cover 490 in place.

DEP-GFET device chip 400 includes an array of isolated and independently operated DEP-GFET devices. Specifically, DEP-GFET device chip 400 includes eight isolated and independently operated DEP-GFET devices: first DEP-GFET device 410, second DEP-GFET device 411, third DEP-GFET device 420, fourth DEP-GFET device 421, fifth DEP-GFET device 430, sixth DEP-GFET device 431, seventh DEP-GFET device 440 and eighth DEP-GFET device 441. DEP-GFET device chip 400 is configured so that the isolated and independently operated DEP-GFET devices form pairs of duplicate, redundant sensors, or channels, in the event one of the pair of DEP-GFET devices fails. Each pair of duplicate, redundant sensors include identical surface functionalization. In DEP-GFET device chip 400, first DEP-GFET device 410 and second DEP-GFET device 411 form a first sensor channel; third DEP-GFET device 420 and fourth DEP-GFET device 421 form a second sensor channel; fifth DEP-GFET device 430 and sixth DEP-GFET device 431 form a third sensor channel; and seventh DEP-GFET device 440 and eighth DEP-GFET device 441 form a fourth sensor channel. Since each of the DEP-GFET devices that comprise a pair include identical surface functionalization, each DEP-GFET device within a pair is expected to attract and evaluate the presence of the same type of analyte. However, the four redundant pairs of sensors on chip 400, i.e., the four sensor channels, may include different surface functionalization designed to attract different analyte, such that chip 400 attracts and evaluates the presence of four different types of analytes.

Specifically, chip 400 is configured so that the first sensor pair made up of first DEP-GFET device 410 and second DEP-GFET device 411 includes surface functionalization comprising probes for a seasonal influenza; the second sensor pair made up of third DEP-GFET device 420 and fourth DEP-GFET device 421 includes surface functionalization comprising probes for SARS-COV-2 Delta virus; the third sensor channel made up of fifth DEP-GFET device 430 and sixth DEP-GFET device 431 includes surface functionalization comprising probes for SARS-39 CoV-2 Delta Plus; and the fourth sensor channel made up of seventh DEP-GFET device 440 and eighth DEP-GFET device 441 includes surface functionalization comprising probes for SARS-COV-2 Gamma. Such a configuration enables evaluation of the presence of each of these four different viruses in a sample using a single DEP-GFET device chip 400.

In FIG. 4B, DEP-GFET device chip 400 is depicted with cover 490 in place on top of device. Cover 490 is configured to substantially cover the top surface of chip 400 except for four regions, each region exposing a duplicate pair of DEP-GFET devices. Cover 490 is a polydimethylsiloxane (PDMS) cover fabricated to expose each of the four regions to the electrolyte solution that may include a biological sample but otherwise protect components of chip 400 from exposure to such electrolyte solution. Each exposed region of chip 400 is configured as a well or microfluidic region or microfluidic channel that exposes the channel region (and therefore the graphene layer with associated surface functionalization) of each DEP-GFET device pair that comprises the well or microfluidic channel. Each well or microfluidic region is isolated from each other. First well or microfluidic region 491 is configured to expose first DEP-GFET device 410 and second DEP-GFET device 411 configured to evaluate the presence of seasonal influenza; second well or microfluidic region 492 is configured to expose third DEP-GFET device 420 and fourth DEP-GFET device 421 configured to evaluate the presence of SARS-COV-2 Delta; third well or microfluidic region 493 is configured to expose fifth DEP-GFET device 430 and sixth DEP-GFET device 431 configured to evaluate the presence of SARS-COV-2 Delta Plus; and fourth well or microfluidic region 494 is configured to expose seventh DEP-GFET device 440 and eighth DEP-GFET device 441 configured to evaluate the presence of SARS-COV-2 Gamma.

### Applications

Devices and systems of the invention find use in a variety of applications. In some instances, devices and systems find use in detecting the presence of analytes (i.e., target analyte) with medical implications. For example, devices and systems may be configured to detect the presence of an infection or analytes capable of causing infection, such as, for example, viruses or virus fragments, in a biological sample. Devices and systems of the invention find use in rapid detection of analytes of interest (i.e., target analyte), for example, in the context of traditional medical laboratory techniques, such as rapid detection in the context of home testing or telehealth medicine. Devices and systems of the invention may further find use in screening for conditions, such as, for example, screening for SARS-COV-2 infection and/or influenza infection. However, the present device and system and teachings are not solely limited to detection of conditions in the context of medicine or conditions with medical implications and may be generally applied to other applications as determined by those skilled in the art.

The devices and systems may be used for evaluating the presence of analyte in samples, such as biological samples, collected from any number of different subjects, as described above. In some instances, the subjects are “mammals” or “mammalian,” where these terms are used broadly to describe organisms which are within the class mammalia, including the orders carnivore (e.g., dogs and cats), rodentia (e.g., mice, guinea pigs, and rats), and primates (e.g., humans, chimpanzees, and monkeys). In some instances, the subjects are humans.

The methods, devices, systems and kits provided herein can be used in any appropriate application. Examples of applications for which the methods, devices, systems and kits provided herein can be used include, without limitation, antimicrobial resistance testing, therapy monitoring, biomedical diagnostics (e.g., screening for infection (e.g., screening for viral infection, such as SARS-COV-2 or seasonal influenza infection), diagnostics of surgical site infections, bloodstream infections and/or inflammatory masses), drug screening, environmental contamination assessment, food safety assessments, the development (e.g., discovery) and commercialization of new drugs and/or pharmaceutical compounds.

In some cases, the methods, devices, systems and kits provided herein can be used to identify the presence of a virus based, at least in part, on the presence, absence or amount of one or more analytes in a sample. Examples of viruses (e.g., potentially infectious viruses) that can be detected using the methods, devices, systems and kits provided herein include, without limitation, human immunodeficiency virus (e.g., HIV1 and HIV2), Zika virus, influenza virus A and B, adenovirus 4, RSV, parainfluenza types 1, 2 and 3, human coronaviruses OC43, 229E and HK, human metapneumovirus, rhinoviruses, enteroviruses, hepatitis A, B, C and E viruses, rotavirus, human papillomavirus, measles viruses, caliciviruses, astrovirus, West Nile virus, Ebola virus, Dengue fever virus, African swine fever, herpes simplex virus (e.g., HSV-2), Norwalk and Norwalk-like viruses, enteric adenoviruses, yellow fever virus, chikungunya virus, Epstein-Barr virus, parvovirus, varicella zoster virus and Ross River virus, as well as seasonal influenza viruses or coronaviruses, e.g., SARS-COV-2 viruses, such as SARS-COV-2 variants, e.g., SARS-COV-2 Alpha, SARS-COV-2 Beta, SARS-COV-2 Delta or SARS-COV-2 Delta Plus, SARS-COV-2 Gamma or SARS-COV-2 Omicron.

In some cases, the methods, devices, systems and kits provided herein can be used to identify the presence of a microorganism (e.g., bacteria, fungi and protozoa) based, at least in part, on the presence, absence or amount of one or more analytes in a sample. For example, an embodiment of a method, device, system or kit provided herein can be configured for microorganism diagnostics, e.g., screening for potentially infecting microorganisms. In some cases, methods, devices, systems and kits provided herein can be used to identify the presence of an antimicrobial resistant bacteria (e.g., methicillin-resistant Staphylococcus aureus (MRSA) and methicillin-sensitive S. aureus (MSSA)). Examples of microorganisms (e.g., potentially infecting microorganisms) that can be detected using the methods, devices, systems and kits provided herein include, without limitation, bacterial microorganisms such as Staphylococcus aureus (e.g., MRSA and MSSA), Streptococcus pyogenes, Streptococcus pneumoniae, Mycoplasma pneumoniae, Haemophilus influenzae, Chlamydia pneumoniae, Bordelella pertussis, Mycobacterium tuberculosis, E. coli (e.g., enterohaemorrhagic E. coli such as 0157:H7E. coli or enteropathogenic E. coli), Salmonella species (e.g., Salmonella enterica), Listeria monocytogenes, Acinetobacter baumanni, Klebsiella oxytoca, Giardia intestinalis, Sarcoptes scabiei, Neisseria gonorrhoeae, Chlamydia trachomatis, Treponema pallidum, Campylobacter species (e.g., thermophilic strains of Campylobacter jejuni, C. lari or C. coli), Bacillus cereus, Vibrio species, Yersinia enterocolitica, Shigella species, Enterococcus species (e.g., Enterococcus faecalis or E. faecium), Helicobacter pylori and Clostridium species (e.g., Clostridium botulinum or Clostridium perfringens), fungal microorganisms such as Aspergillus species (e.g., A. flavus, A. fumigatus and A. niger), yeast (e.g., Candida norvegensis and C. albicans), Penicillium species, Rhizopus species and Alternaria species and protozoan microorganisms such as Cryptosporidium parvum, Giardia lamblia and Toxoplasma gondii.

### Sample:

Any appropriate sample can be evaluated (e.g., for the presence, absence or amount of one or more analytes) using the methods, devices, systems and kits provided herein. In some cases, a sample can be a biological sample. In some cases, a sample can be an environmental sample. A sample can contain one or more analytes (e.g., proteins, nucleic acids, intact cells, cellular fragments, intact viruses, virus fragments, intact microorganisms, microorganism fragments and/or chemicals). For example, a sample can contain whole cells, cellular fragments, DNA, RNA, viruses, virus fragments and/or proteins. Examples of samples that can be used in the methods, devices, systems and kits described herein include, without limitation, biological samples (e.g., blood (e.g., whole blood, a blood spot, serum or plasma) samples, urine samples, saliva samples, mucus samples, sputum samples, bronchial lavage samples, fecal samples, buccal samples, nasal samples, amniotic fluid samples, cerebrospinal fluid samples, synovial fluid samples, pleural fluid samples, pericardial fluid samples, peritoneal fluid samples, urethral samples, cervical samples, genital sore samples, hair samples and skin samples), environmental samples (e.g., water samples, soil samples and air samples), food samples (e.g., meat samples, produce samples or drink samples), plant samples (e.g., leaf samples, root samples, flower samples, stem samples, pollen samples and seed samples), industrial samples (e.g., air filter samples, samples collected from work stations, samples collected from storage facilities and/or products (e.g., grain silos), and samples collected from transportation machinery (e.g., railroad cars, trucks or pipelines)). In some cases, the methods, devices, systems and kits provided herein can retain the sample for safe and clean disposal.

A sample to be evaluated (e.g., for the presence, absence or amount of one or more analytes) using the methods, devices, systems and kits provided herein can be obtained using any appropriate technique. For example, biological samples can be obtained using non-invasive (e.g., swab) techniques or invasive techniques (e.g., venipuncture, finger stick or biopsy). For example, an environmental sample and/or an industrial sample can be obtained using a surface swab technique. In some cases, a sample can be a liquid sample. A liquid sample can be any appropriate volume. For example, a liquid sample can include from about 10 microliters (μL) to about 10 mL (e.g., from about 10 μL to about 8 mL, from about 10 μL to about 5 mL, from about 10 μL to about 3 mL, from about 10 μL to about 2 mL, from about 10 μL to about 1 mL, from about 10 μL to about 500 μL, from about 10 μL to about 250 μL, from about 10 μL to about 100 μL, from about 10 μL to about 50 μL, from about 25 μL to about 8 mL, from about 50 μL to about 7 mL, from about 100 μL to about 5 mL, from about 250 μL to about 2 mL, from about 500 L to about 1 mL, from about 25 μL to about 20 mL, from about 50 μL to about 20 mL, from about 250 μL to about 20 mL, from about 500 μL to about 20 mL, from about 1 mL to about 20 mL, from about 5 mL to about 20 mL, from about 10 mL to about 20 mL, from about 15 mL to about 20 mL).

A sample to be evaluated (e.g., for the presence, absence or amount of one or more analytes) using the methods, devices, systems and kits provided herein can be obtained from any appropriate species. In some cases, a sample to be assessed as described herein can be obtained from an animal. In some cases, a sample to be assessed as described herein can be obtained from a mammal (e.g., a human). Examples of mammals that samples can be obtained from include, without limitation, primates (e.g., humans and monkeys), dogs, cats, horses, cows, pigs, sheep, rabbits and rodents (e.g., mice and rats). Other examples of animals that samples can be obtained from include, without limitation, fish, avian species (e.g., chickens, turkeys, ostrich, emus, cranes, and falcons) and non-mammalian animals (e.g., mollusks, frogs, lizards, snakes and insects).

A sample to be evaluated (e.g., for the presence, absence or amount of one or more analytes) using the methods, devices, systems and kits provided herein can be obtained from any appropriate plant. In some cases, a sample to be assessed as described herein can be obtained from a crop plant (e.g., corn). Examples of plants include, without limitation, corn, soybeans, wheat, rice, trees, flowers, shrubs, grains, grasses, legumes and fruits.

In some cases, a sample to be evaluated (e.g., for the presence, absence or amount of one or more analytes) using the methods, devices, systems and kits provided herein can be obtained from a source (e.g., a mammal or surface) and processed prior to being introduced to a device or system provided herein (e.g., can be pre-processed). Samples that are pre-processed can be pre-processed using one or more appropriate reagents (e.g., enzymes, acids, bases, buffers, detergents, anticoagulants, and/or aptamers) and/or techniques (e.g., purification techniques, centrifugation techniques, amplification techniques, culturing techniques and/or denaturing techniques). For example, a blood sample can be obtained from a mammal (e.g., a human) and treated with one or more anticoagulants. Examples of anticoagulants that can be used to pre-process a sample (e.g., a blood sample) include, without limitation, EDTA, citrate (trisodium citrate), heparinates (e.g., sodium, lithium, or ammonium salt of heparin or calcium-titrated heparin), and hirudin. In some cases, a sample (e.g., a sample suspected to contain a microorganism) to be to be introduced to a device or system provided herein can be obtained from a source (e.g., a food preparation surface) and pre-processed by culturing the sample with appropriate culture media for a period of time (e.g., four hours to 24 hours) prior to being introduced to a device or system described herein. Examples of other pre-processing techniques that can be performed prior to introducing the sample to a device or system provided herein include, without limitation, centrifugation to obtain cell containing material, centrifugation to obtain cell-free material, filtration to remove cell containing material, cell lysis, nucleic acid purification, protein purification, nucleic acid amplification (e.g., polymerase chain reaction (PCR)), reverse transcription to obtain complementary DNA (cDNA), reverse transcription PCR, nucleic acid denaturation and isothermal amplification.

In some cases, a sample does not require any processing prior to or after being introduced into a device or system provided herein. For example, a sample (e.g., a sample without any pre-processing or a sample that was pre-processed) can be introduced into a device or system provided herein and directly evaluated via such device or system without any sample processing being performed within such device or system.

In some cases, the methods, devices, systems and kits provided herein can be designed to process a sample (e.g., a sample without any pre-processing or a sample that was pre-processed) after the sample is introduced into a device or system provided herein. For example, a sample can be introduced into a device or system provided herein, subjected to one or more processing steps within such device or system (e.g., one or more processing steps designed to lyse cells and/or one or more processing steps designed to denature nucleic acid) and evaluated by such device or system.

### Analyte:

The methods, devices, systems and kits provided herein can be used to detect any appropriate analyte. Examples of analytes that can be detected as described herein include, without limitation, proteins, nucleic acids, intact cells, viruses (e.g., intact viruses or viral fragments), microorganisms (e.g., intact microorganisms or microorganism fragments) and chemicals. In some cases, the methods, devices, systems and kits provided herein can be used to identify an analyte. For example, the methods, devices, systems and kits provided herein can be used to identify a bacterial analyte or a viral analyte. For example, the methods devices and systems provided herein can be used to determine whether the analyte is a bacterial analyte or a viral analyte. In cases where an analyte to be detected is a protein, the protein analyte can be any appropriate protein (e.g., mammalian protein, viral protein, bacterial protein, fungal protein, plant protein or animal protein). In some cases, a protein analyte can be a polypeptide fragment of protein. In some cases, a protein analyte can be an enzyme, receptor, structural protein, immunoglobulin or cell surface marker. For example, a protein analyte can be a viral protein produced by a cell (e.g., a human cell) that was infected with a particular virus. In some cases, a protein analyte to be detected as described herein can be a protein expressed by a tumor cell (e.g., a tumor marker). In some cases, a protein analyte can include one or more modified amino acids. In some cases, a protein analyte can include one or more post-translational modifications (e.g., phosphorylation, myristoylation, farnesylation, acylation, acetylation and/or methylation modifications). In some cases, a protein analyte to be detected as described herein can be associated with a disease and/or infection. Examples of proteins that can be detected using the methods, devices, systems and kits provided herein include, without limitation, prostate specific antigen (PSA), carcinoembryonic antigen (CEA), cancer antigen 125 (CA 125), cancer antigen 15-3 (CA 15-3), alpha fetoprotein (AFP), hemoglobin, albumin, ferritin, transferrin, haptoglobin, ceruloplasmin, IgA, IgG, IgM, IgE, complement C3, complement C4, fibrinogen, HIV protein p24, penicillin binding protein 2A (PBP2A), troponin, c-reactive protein, procalcitonin, peptide hormones (e.g., follicle-stimulating hormone (FSH), luteinizing hormone (LH), human chorionic gonadotropin (hCG), thyroid stimulating hormone (TSH)), NS1, ENV, interleukins, CD3, CD4, CD47, VP40, human epidermal growth factor receptor 2(HER 2 ), epidermal growth factor receptor (EGRF), CD10, CD30 and B-Raf. Examples of viral proteins that can be detected as described herein include, without limitation, coronaviral spike proteins from SARS viruses, e.g., SARS-COV-2 spike protein to detect SARS-COV-2, NS1 polypeptide of Zika viruses to detect Zika virus, NS1 polypeptide of Dengue fever viruses to detect Dengue fever virus, NS1 polypeptide of West Nile viruses to detect West Nile virus, ENV polypeptide of Dengue fever viruses to detect Dengue fever virus, ENV polypeptide of Zika viruses to detect Zika virus, ENV polypeptide of West Nile viruses to detect West Nile virus, ENV polypeptide of Chikungunya viruses to detect Chikungunya virus and VP40 polypeptide of Ebola viruses to detect Ebola virus.

In cases where an analyte to be detected is a nucleic acid, the nucleic acid analyte can be any appropriate nucleic acid (e.g., mammalian nucleic acid, viral nucleic acid, bacterial nucleic acid, fungal nucleic acid, plant nucleic acid or animal nucleic acid). A nucleic acid analyte can include DNA, RNA, or a combination thereof (e.g., a DNA/RNA hybrid). In some cases, a nucleic acid analyte can be a single stranded nucleic acid. In some cases, a nucleic acid analyte can be a double stranded nucleic acid. In some cases, a nucleic acid analyte can be a circulating nucleic acid. In some cases, a nucleic acid analyte can be used to identify the presence of an antimicrobial resistant bacteria (e.g., MRSA and MSSA). For example, the methods, devices, systems and kits provided herein can be used to identify antimicrobial resistance genes (e.g., a Klebsiella pneumoniae carbapenemase (KPC) gene, a New Delhi metallo-3-lactamase (NDM) gene, an oxacillinase 48 (OXA48 ) gene, a methicillin-resistant (mecA) gene and a vancomycin-resistant (vanA or vanB) gene). In some cases, a nucleic acid analyte can be used in forensic applications (e.g., to compare the identity between samples or to assess a sample's origin). For example, the methods, devices, systems and kits provided herein can be used to identify a DNA fingerprint and/or detect one or more sex chromosomes. In some cases, a nucleic acid analyte can be associated with a disease and/or infection. For example, a nucleic acid analyte can be a genetic marker (e.g., a nucleic acid mutation such as single nucleotide polymorphisms (SNPs), genome duplications (e.g., gene duplications), genome rearrangements, nucleotide repeats (e.g., triplet repeats such as CAG (cytosine-adenine-guanine) repeats) and genome epigenetic events (e.g., DNA methylation events)). Examples of nucleic acids that can be detected using the methods, devices, systems and kits provided herein include, without limitation, an X chromosome, a Y chromosome, Zika virus RNA, HIV virus RNA, Epstein Barr virus DNA, telomeres, a BRCA1 gene, a BRCA2 gene, ABCR genes, a LRRK2 gene, a dystrophin gene, a cystic fibrosis transmembrane conductance regulator (CFTR) gene, a Huntingtin gene, a hemoglobin gene, KPC, NDMA, OXA48, mecA, vanA, and vanB.

In cases where an analyte to be detected is a chemical, the chemical analyte can be any appropriate chemical (e.g., vitamin, mineral, hormone, heavy metal, chemical toxin, chemical carcinogen, drug, electrolyte, small molecule, chemical by-product, chemical metabolite or chemical waste product). For example, particular examples of chemicals that can be detected using the methods, devices, systems and kits provided herein include, without limitation, glucose, vitamins (e.g., vitamin B12 and folic acid), cholesterol, triglycerides, high density lipoprotein (HDL), low density lipoprotein (LDL), very low density lipoprotein (VLDL), sodium (Na⁺), potassium (K⁺) and chloride (Cl⁻), calcium (Ca⁺⁺), phosphorus (PO₄⁻³), magnesium (Mg⁺⁺), iron (Fe⁺⁺), lead (Pb), bilirubin (e.g., total bilirubin, direct bilirubin, indirect bilirubin, and neonatal bilirubin), lactic acid, uric acid, creatinine, urea nitrogen (BUN), ammonia (NH₄⁺), thyroid stimulating hormone (TSH), estrogen, testosterone, beta-human chorionic gonadotropin (beta-HCG), ethanol (alcohol), amphetamines, barbiturates, cannabinoids, opiates and phencyclidine (PCP).

Further details regarding applications in which the subject devices, systems, kits and methods find use are described in U.S. Patent Application Pub. No. 2019/0262827 A1, International Pub. No. WO 2012/145247 A1, International Pub. No. WO 2019/236690 A1 and U.S. Patent Application Pub. No. 2018/0361400, the disclosures of which are herein incorporated by reference.

### Methods

Methods of evaluating a sample for the presence of an analyte are also provided and similarly find benefit in the applications described above. Methods according to the present invention comprise introducing the sample into a bifunctional graphene dielectrophoresis (DEP)-graphene field effect transistor (GFET) device. Such a bifunctional graphene dielectrophoresis (DEP)-graphene field effect transistor (GFET) device, as described above, comprises a graphene dielectrophoresis (DEP) component and a graphene field effect transistor (GFET) component, wherein the graphene DEP and GFET components are independently operable.

Methods according to the present invention further comprise obtaining a result from the device providing information as to whether the analyte is present in the sample.

By “introducing the sample” into a device, it is meant exposing the sample, which may be a biological sample, or aspects derived from a biological sample, as described in detail above, present in, e.g., an electrolyte buffer that is the liquid top gate of the device, as described above, to a surface of a graphene layer of the device. As described above, exposing target analyte to a surface of a graphene layer of the device may cause electrical characteristics of the device to change in a manner that can be detected, thereby indicating the presence of target analyte in the biological sample present in the fluid of the liquid top gate.

By “obtaining a result from the device,” it is meant detecting such a change in electrical characteristics of the device and applying such observations to evaluate whether analyte is present in the sample. For example, as described above, the change in electrical characteristics of the device may comprise, for example, a change in the magnitude of current flowing through the drain of the device (while other voltage biases remain substantially constant) or a change in the Dirac point of the device. In the event analyte (i.e., target analyte) is present in the sample, a change in electrical properties of the device may be indicative of the presence of such analyte. In the event analyte (i.e., target analyte) is not present in the sample, such electrical properties of the device are not expected to change. As such, no indication of a change in the electrical properties of the device is indicative of the absence of analyte in the biological sample.

### DEP Functionality:

As described above, the DEP component of the device may be configured to apply a dielectrophoretic (DEP) force, e.g., a DEP force capable of attracting analyte, if any, present in the biological sample included in the liquid top gate, towards the device so that such analyte causes electrical properties of the device to change in a detectable manner.

As described above, in embodiments, the graphene DEP component of the device comprises: a graphene layer, a source electrode electrically connected to the graphene layer and a bottom gate electrode separated from the source electrode by a dielectric layer. Embodiments of methods according to the present invention further comprise applying a bottom gate bias (V_{BG}) to the bottom gate electrode sufficient to cause the graphene layer to apply a dielectrophoretic force. That is, application of such bias applied to the bottom gate electrode causes the graphene layer to apply a DEP force. In embodiments, the bottom gate bias (V_{BG}) is an AC bias comprising a specified frequency (v) and a specified peak-to-peak voltage (V_{PP}). Any convenient bottom gate bias (V_{BG}) sufficient to cause the graphene layer to apply a dielectrophoretic force may be applied, and such may vary, for example, the specified frequency (v) of such bias may range from 100 Hz to 50 MHz, including for example from 10 kHz to 10 MHz or 500 kHz to 5 MHz or 800 kHz to 8 MHz, and the specified peak-to-peak voltage (V_{PP}) of such bias may range from 0.1 to 20 Volts, including for example from 0.5 to 5 Volts or 1 to 3 Volts. In some cases, the peak-to-peak voltage (V_{PP}) is held constant, and, in other cases, the peak-to-peak voltage (V_{PP}) is not held constant.

In some embodiments, the graphene layer applies the dielectrophoretic force within a device channel region located between the source and drain electrodes, wherein the graphene layer is present within the channel region. That is, the device may be configured to include a channel region located between the source and drain electrodes and including the graphene layer or sections thereof. As described above, such channel region may be configured to receive fluid of the top gate, where a biological sample may be included in such fluid such that target analyte, if any is present in the biological sample, may be attracted to the channel region of the device. In some embodiments, the dielectrophoretic force is a positive dielectrophoresis force. That is, the dielectrophoretic force may cause analyte to be attracted to the device. In other embodiments, the dielectrophoretic force is a negative dielectrophoresis force. That is, the dielectrophoretic force may cause analyte to be repelled from the device. The nature of the dielectrophoretic force (i.e., positive versus negative) may be based at least in part on the specified frequency (v) and/or the specified peak-to-peak voltage (V_{PP}) of the bottom gate bias (V_{BG}) applied to the bottom gate of the device.

### GFET Functionality:

As described above, the GFET component of the device may be configured to evaluate electrical properties of the device, e.g., a drain current (I_{D}) or a Dirac point of the device, and to detect changes in such electrical properties of the device. Changes in such electrical properties of the device may be caused by the presence of analyte in the biological sample included in the liquid top gate so that such analyte causes electrical properties of the device to change in a detectable manner. In embodiments, the GFET component may be configured to act as a sensor, e.g., a biosensor.

As described above, in embodiments, the GFET component of the device comprises: the graphene layer, the source electrode, a drain electrode electrically connected to the graphene layer and separated from the source electrode, and a top gate electrode separated from the graphene layer, the source and drain electrodes and the bottom gate electrode. In embodiments, obtaining a result from the device providing information as to whether the analyte is present in the sample comprises: exposing the graphene layer to the sample, simultaneously applying a drain bias (V_{D}) comprising a DC bias to the drain electrode and a top gate bias (V_{TG}) to the top gate electrode and measuring an electrical property of the device. In some cases, the top gate bias (V_{TG}) is a DC bias and measuring the electrical property of the device comprises measuring a drain current (i.e., a magnitude of current flowing through the drain of the device). In other cases, the top gate bias (V_{TG}) comprises a voltage sweep and measuring the electrical property of the device comprises measuring a Dirac point response of the device. In such embodiments, the top gate bias (V_{TG}) voltage sweep may span a Dirac voltage of the device.

### Simultaneously Attracting and Sensing Analyte:

As described above, the graphene DEP and GFET components of embodiments of the device are independently operable. That is, embodiments of the device can be operated such that the DEP component can be used to apply a DEP force separately and independently of operating the GFET component of the device. Such independent operation of the components of the device enables finer grain operation of the device resulting in improved sensitivity and specificity of evaluating a sample for the presence of analyte. Further, embodiments of the device can be operated such that the DEP and GFET components are operated simultaneously. In particular, in embodiments, exposing the graphene layer to the sample comprises applying a bottom gate bias (V_{BG}) to the bottom gate electrode sufficient to cause the graphene layer to apply a dielectrophoretic force. That is, a bottom gate bias (V_{BG}) is applied to the bottom gate of the device simultaneously with exposing the sample to the device where the GFET component of the device is engaged to evaluate the sample for the presence of analyte, if any.

### Other Aspects of Methods:

Embodiments of methods according to the present invention further comprise using a flow cell to flow fluid over the device. Any convenient flow cell may be applied as such are known in the art. Such flow cell may be configured to flow fluid over the device, where such fluid is the top gate of the device. A flow cell may be applied to flow fluids with different characteristics over the device such that fluids with different characteristics act as the liquid top gate of the device during different time periods. For example, a flow cell may be used to flow fluid to apply a liquid top gate comprising an electrolyte buffer of a specified concentration as an experimental control. The flow cell may subsequently flow fluid to apply a liquid top gate, where such fluid comprises the electrical buffer at the specified concentration as well as a biological sample, which may or may not comprise analyte (i.e., target analyte). A flow cell may be used in conjunction with a device that further comprises a cover configured to form a well over the channel region of the device.

As described above, methods for evaluating a sample for the presence of an analyte may be used in the context of evaluating physiologically relevant conditions, such as medical conditions, such as infection, such that in some embodiments, the method is a method for screening for or diagnosing certain conditions. For example, in some cases, a method of the present invention is a method of screening for SARS-COV-2 infection and/or seasonal influenza infection in a subject. In some instances, the biological sample is derived from subjects that are “mammals” or “mammalian,” where these terms are used broadly to describe organisms which are within the class mammalia, including the orders carnivore (e.g., dogs and cats), rodentia (e.g., mice, guinea pigs, and rats), and primates (e.g., humans, chimpanzees, and monkeys). In some instances, the subjects are humans.

### Kits

Also provided are kits that include a device, e.g., as described above, as well as packaging for the device, which packaging may be sterile, as desired. Components of the kit may be disposable or reusable, as desired. In some cases, kits may comprise a plurality of devices including multiple versions of the same device with different characteristics, such as, for example, different electrical characteristics or different surface functionalization tailored to different target analyte.

Kits according to the present invention may also include a power supply for the device. Any convenient power supply capable of causing each of the DEP component and the GFET component of the device to operate in the intended manner may be applied. Such a power supply may include a voltage source configured to provide voltage potentials to the bottom gate electrode and/or the drain electrode and/or the source electrode and/or the top gate electrode of the device, e.g., V_{BG}, V_{D}, V_{S} or V_{TG}, as described above. Power supplies of interest may include, for example, a battery or an electrical connector for connecting the power supply to an external power source such as a plug-in power source.

In embodiments of kits according to the present invention, the packaging for the device comprises a cartridge configured to house the device. Any convenient cartridge may be applied, such as, for example, a cartridge that facilitates the device being held and manipulated by hand or a cartridge that facilitates, e.g., provides a substrate for, sample collection or connecting a power supply or connecting a transmitter.

Kits according to the present invention may also include a sample collection device. Any convenient sample collection device capable of collecting a sample of interest may be applied. For example, sample collection devices may be configured to collect nasal swabs, throat swabs, check swabs, saliva, urine or the like. Sample collection devices of interest may be configured to interface with a device according to the present invention or packaging therefor such that any sample collected by the sample collection device can be delivered to the device, e.g., the graphene layer of the channel region of the device for evaluation of whether target analyte is present in the sample.

In some embodiments, the sample collection device comprises sample transport media. Any convenient sample transport media may be applied, such as, for example, sample transport media configured to maximize sample stability and/or preserve aspects of the sample prior to and/or while the sample is exposed to the device. For example, sample transport media may be configured to preserve target analyte present in the sample. In some cases, transport media may comprise an inert buffer or dilutant. In other cases, transport media contain one or more constituents that preserve certain sample characteristics (e.g., prevent the breakdown of a cell wall or a cell membrane by cell lysis). In addition, some of these constituents may serve the dual purpose of preservation and decontamination of the sample. Embodiments may comprise a transport media that does not affect the electrical characteristics of the device, e.g., via the graphene layer of the device or aspects of surface functionalization of the graphene layer, as described herein.

In embodiments, the device of the kit is a component of a multiplex analyte sensing chip, such as those described above. In some embodiments, the multiplex analyte sensing chip comprises a control. The control may be any experimental control of interest, such as a control configured to confirm that a sample was exposed to the device and/or that the device is functioning correctly to evaluate the presence of a target analyte in a sample. In some cases, the control comprises a positive control. Such a positive control may be configured to confirm that a sample has been exposed to the device and/or that the device is capable of evaluating the presence of an analyte correctly. In other cases, the control comprises a negative control. Such a negative control may be configured to confirm that the device is capable of evaluating the presence of an analyte correctly. In still other cases, the control comprises both a positive and a negative control.

Also provided are kits that include a system, e.g., as described above, as well as packaging for the system, which packaging may be sterile, as desired.

Also present in the kit may be instructions for using the kit components. The instructions may be recorded on a suitable recording medium. For example, the instructions may be printed on a substrate, such as paper or plastic, etc. As such, the instructions may be present in the kits as a package insert, in the labeling of the container of the kit or components thereof (i.e., associated with the packaging or sub-packaging) etc. In other embodiments, the instructions are present as an electronic storage data file present on a suitable computer readable storage medium, e.g., portable flash drive, DVD-or CD-ROM, etc. The instructions may take any form, including complete instructions for how to use the device or system or as a website address with which instructions posted on the world wide web may be accessed.

The following example(s) is/are offered by way of illustration and not by way of limitation.

### EXAMPLES

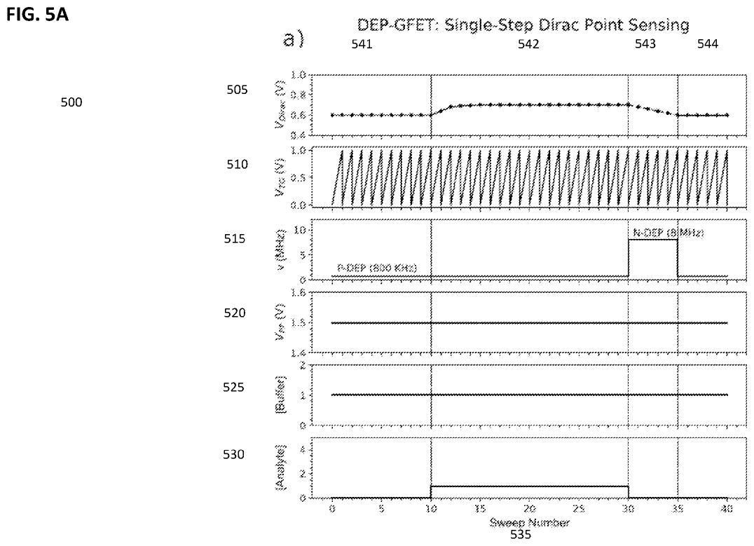

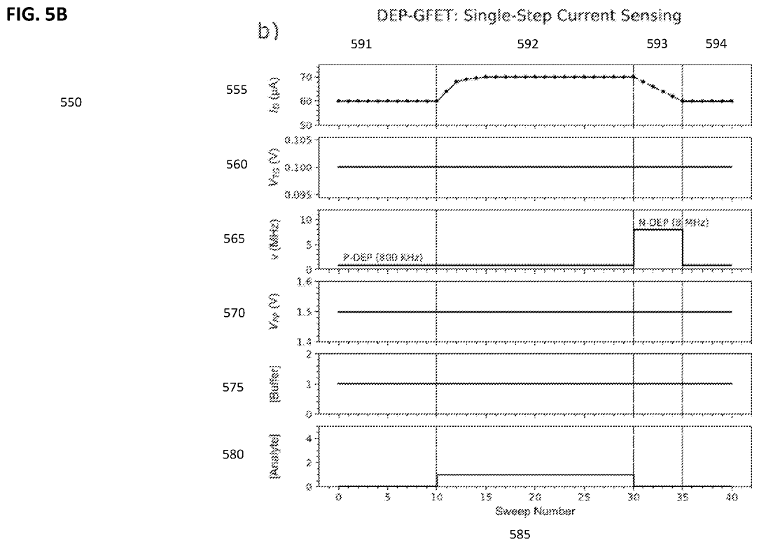

FIGS. 5A and 5B provide example sensing modes for embodiments of a DEP-GFET device according to the present invention. FIG. 5A provides an example of single-step Dirac point sensing. FIG. 5B provides an example of single-step current sensing.

FIGS. 5A and 5B present electrical properties of a device according to the present invention, such as, for example, device 100 depicted in FIG. 1 or device 200 depicted in FIG. 2 or device 300 depicted in FIG. 3 or any one of the eight DEP-GFET devices present on chip 400, such as, for example, first DEP-GFET device 410.

### Single Step Dirac Point Sensing:

FIG. 5A presents six plots of experimental results 500 of electrical characteristics of a device according to the present invention and illustrates how the device according to the present invention may be used to trap analyte and evaluate the presence of analyte using Dirac point sensing. Each plot shares a common x-axis 535 that presents time with reference to “Sweep Numbers” (referring to voltage sweeps of V_{TG}), such that the electrical characteristics of the device according to the present invention are, in each case, presented as a function of time (i.e., “Sweep Number”). Horizontal lines in each plot are drawn at Sweep Number 10, Sweep Number 30 and Sweep Number 35 that demarcate four experimental steps: first step 591 between Sweep Numbers 0 and 10; second step 592 between Sweep Numbers 10 and 30; third step 593 between Sweep Numbers 30 and 35; and fourth step 594 between Sweep Numbers 35 and 40.

In experimental results 500, Dirac point sensing is performed using a device according to the present invention, in particular, using a flow cell in conjunction with such device that is configured to allow for switching of an electrolyte buffer solution interacting with the graphene channel of the device.

Dirac point sensing is a technique for evaluating the presence of analyte in a biological sample, where the channel region of the device is exposed to an electrolyte solution with the biological sample that may contain the target analyte. Dirac point sensing works by sensing a change in the Dirac point of the GFET component of the device caused by the presence of target analyte in the channel region of the device, specifically, the interaction between the target analyte and the graphene channel of the device.

In connection with conducting Dirac point sensing, voltage potentials are applied to electrodes of the device such that the device operates in a combined DEP and GFET regime.

The electrical connections and voltage potentials applied to the device resulting in electrical characteristics 500 are similar to the electrical connections described in connection with device 200 in FIG. 2.

In order to operate in the DEP regime, the bottom gate electrode of the device is connected to V_{BG} , an AC bias, characterized by a frequency (v) and a peak-to-peak voltage (V_{PP}). The voltage source supplying the AC bias of V_{BG} has control over both frequency (v) and peak-to-peak voltage (V_{PP}) of V_{BG} . The frequency (v) of V_{BG} is depicted in plot 515 where the y-axis represents frequency (v) in MHz. As described above, applying V_{BG} at certain frequencies causes the device (specifically, the edges formed where the graphene layer crosses the bottom gate electrode) to apply a dielectrophoretic force in a positive or negative direction (i.e., a force attracting analyte to the channel region or repelling analyte away from the channel region). As seen in plot 515, V_{BG} is applied to the bottom gate electrode at a frequency (v) of 800 KHZ between Sweep Number 0 and Sweep Number 30 causing the device to generate a positive dielectrophoretic force (P-DEP) to attract target analyte to the channel region of the device.

Between Sweep Number 30 and Sweep Number 35, V_{BG} is applied to the bottom gate electrode at a frequency (v) of 8 MHz causing the device to generate a negative dielectrophoretic force (N-DEP) to repel target analyte from the channel region of the device. Between Sweep Number 35 and Sweep Number 40, V_{BG} is applied to the bottom gate electrode at a frequency (v) of 800 kHz causing the device to generate a positive dielectrophoretic force (P-DEP) to attract target analyte to the channel region of the device. The peak-to-peak voltage (V_{PP}) of V_{BG} is depicted in plot 520 where the y-axis represents peak-to-peak difference in voltage in Volts (V). As seen in plot 520, the peak-to-peak voltage (V_{PP}) of V_{BG} remains constant throughout the course of the experiment.

In order to simultaneously operate in the GFET regime to apply Dirac point sensing for evaluating a sample for the presence of an analyte, the source electrode of the device is electrically connected to ground such that the GFET source is grounded. The drain electrode of the device is electrically connected to V_{D}, a DC bias, such that the electrical potential of the GFET drain differs from that of GFET source by a constant, i.e., a DC, voltage potential.

The top gate electrode of the device is connected to V_{TG} such that the electrical potential of top gate electrode, and therefore the electrical potential of electrolyte liquid top gate, of the device is swept between a low and a high voltage. The voltage sweep of V_{TG} applied to the top gate electrode is shown in plot 510 where the y-axis represents Volts (V). As seen, the voltage of V_{TG} in plot 510 exhibits a saw tooth pattern sweeping from a low voltage to a high voltage, once per each Sweep Number depicted on x-axis 535. As described above, the Dirac point of the GFET component of the device corresponds to the value of V_{TG} at which minimal drain current (I_{D}) (i.e., the absolute value of drain current (I_{D})) is observed across the graphene layer of the channel region of the device. As such, V_{TG} is swept across a range of voltages that span the range of potential Dirac points of the device in order to track a shift in the Dirac point during the experiment, i.e., a shift in the Dirac point of the GFET component of the device resulting from the presence of analyte interacting with the graphene layer in the channel region of the device.

Plot 525 presents the concentration of electrolyte buffer that is flowed over the channel region of the device forming the electrolyte liquid top gate of the device. As seen in plot 525, the electrolyte concentration in the electrolyte buffer used as electrolyte liquid top gate remains constant throughout the experiment (i.e., the concentration remains constant at each Sweep Number).

Plot 530 presents the concentration of target analyte present in the electrolyte buffer solution. As seen in plot 530, target analyte is introduced into the electrolyte buffer solution (and therefore introduced to the channel region of the device) at a constant concentration starting at Sweep Number 10 and is no longer present after Sweep Number 30.

Using a device according to the present invention to evaluate a sample for the presence of an analyte by conducting Dirac point sensing proceeds according to the following four steps. First Step: First step 541 of the experimental process is to establish a baseline reference position of the Dirac point of the device and is seen in experimental results 500 between Sweep Numbers 0 to 10.

During first step 541, the channel region of the device is exposed to electrolyte buffer (i.e., that acts as a liquid top gate of the device) at a constant concentration as shown in plot 525, but the electrolyte buffer includes no target analyte, as shown in plot 530 (where the analyte concentration is shown as zero during this time).

Also, during first step 541, the device is configured to apply a positive dielectrophoretic (DEP) force (i.e., the DEP component of the device is configured to apply a positive dielectrophoretic force) in the channel region of the device. A positive DEP force is caused by applying V_{BG}, an AC bias (i.e., a voltage applied to the bottom gate electrode of the device) at a frequency (v) of 800 kHz. The frequency (v) of the AC bias of V_{BG} is seen in plot 515, where, during first step 541, between Sweep Numbers 0 and 10, a constant frequency (v) of 800 kHz is plotted, and plot 515 is annotated “P-DEP” referring to positive dielectrophoretic force. The peak-to-peak voltage (V_{PP}) of V_{BG} remains constant during first step 541 as seen in plot 520.

Simultaneously with applying V_{BG} in this manner, a baseline Dirac point position is determined, in order to establish a reference for the Dirac point before introducing target analyte. A baseline Dirac point is determined by observing the point at which current through the drain of the device, i.e., drain current (I_{D}), is minimal while the top gate voltage (V_{TG}) is swept across a range of voltages during each of Sweep Numbers 0 to 10 that includes the Dirac point. As seen in plot 510, the top gate voltage V_{TG} is swept across a range of voltages, and based on this, the Dirac point is determined as shown in plot 505. Plot 505, which depicts the Dirac point of the device in Volts over time, shows that the Dirac point is established at a constant voltage (approximately 0.6 V) during the first step 541 that occurs during Sweep Numbers 0 to 10.

Second Step: Second step 542 of the experimental process is to cause analyte response saturation and is seen in experimental results 500 between Sweep Numbers 10 to 30. During second step 542, the channel region of the device continues to be exposed to electrolyte buffer (i.e., that acts as a liquid top gate of the device) at the same constant concentration as in first step 541, as shown in plot 525. Also, during second step 542, analyte is introduced into the electrolyte buffer at a constant concentration, as shown in plot 530 (where the analyte concentration is shown at a constant, non-zero, concentration during second step 542).

Also, during second step 542, the device continues to be configured to apply a positive dielectrophoretic (DEP) force (i.e., the DEP component of the device is configured to apply a positive dielectrophoretic force) in the channel region of the device. The positive DEP force continues to be caused by applying V_{BG}, an AC bias (i.e., a voltage applied to the bottom gate electrode of the device) at a frequency (v) of 800 kHz. The frequency (v) of the AC bias of V_{BG} is seen in plot 515, where, during second step 542, between Sweep Numbers 10 and 30, a constant frequency (v) of 800 kHz is plotted, and plot 515 is annotated “P-DEP” referring to positive dielectrophoretic force. Because a positive DEP force is generated in the channel region of the device, analyte present in the electrolyte buffer is trapped in the channel region of the device. Analyte trapped in the channel region of the device interacts with the graphene layer, changing the electrical properties of the graphene layer of the device such that the Dirac point is expected to shift in response to the presence of analyte trapped in the channel region. Simultaneously with applying V_{BG} in this manner, a shift in the Dirac point position, relative to the baseline position established in the first step, is observed as follows. The shifted Dirac point is determined in the same way the baseline Dirac point is established in first step 541. That is, the shifted Dirac point is determined by observing the point at which current through the drain of the device, i.e., drain current (I_{D}), is minimal while the top gate voltage (V_{TG}) is swept across a range of voltages that includes the Dirac point. As seen in plot 510, the top gate voltage V_{TG} is swept across a range of voltages during each of Sweep Numbers 10 to 30, and based on this, the Dirac point is determined as shown in plot 505. Plot 505, which depicts the Dirac point of the device in Volts over time, shows that the Dirac point shifted upwards to a higher voltage in second step 542 during Sweep Numbers 10 to 30, relative to the baseline Dirac voltage established during Sweep Numbers 0 to 10. The shift in the Dirac point of the device is indicative of the presence of analyte trapped in the channel region such that the device may be used to evaluate the presence of analyte by observing changes, such as the change described above, in the Dirac point of the device.

Third Step: Third step 543 of the experimental process is to de-trap the analyte in the channel region of the device and is seen in experimental results 500 between Sweep Numbers 30 to 35.

During third step 543, the channel region of the device continues to be exposed to electrolyte buffer (i.e., that acts as a liquid top gate of the device) at the same constant concentration as in first and second steps 541 542, as shown in plot 525. Also, during third step 543, analyte is no longer present in the electrolyte buffer, as shown in plot 530 where the analyte concentration is shown at a constant zero concentration during third step 543.

Also, during third step 543, the device is configured to apply a negative dielectrophoretic (DEP) force (i.e., the DEP component of the device is configured to apply a negative dielectrophoretic force) in the channel region of the device. The negative DEP force is caused by applying V_{BG}, an AC bias (i.e., a voltage applied to the bottom gate electrode of the device) at a frequency (v) of 8 MHz. This new frequency (v) of the AC bias of V_{BG} is seen in plot 515, where between Sweep Numbers 30 and 35, a constant frequency (v) of 8 MHz is plotted, and plot 515 is annotated “N-DEP” referring to negative dielectrophoretic force. Because a negative DEP force is generated in the channel region of the device, analyte that had previously been trapped in the channel region of the device is now forced away from, and out of, the channel region. Whereas analyte trapped in the channel region of the device had previously interacted with the graphene layer of the device, changing its electrical properties, including the Dirac point, of the graphene layer of the device, the absence of analyte in the channel region removes such interaction between the analyte and the graphene layer of the device so that the Dirac point is expected to revert to the baseline Dirac point established in the first step 541.

Simultaneously with applying V_{BG} in this manner, a shift in the Dirac point position reverting to the baseline position established in first step 541, is observed in third step 543 as follows. As described previously, the shifted Dirac point is determined by observing the point at which current through the drain of the device, i.e., drain current (I_{D}), is minimal while the top gate voltage (V_{TG}) is swept across a range of voltages that includes the Dirac point. As seen in plot 510, the top gate voltage V_{TG} is swept across a range of voltages during each of Sweep Numbers 30 to 35, and based on this, the Dirac point is determined as shown in plot 505. Plot 505, which depicts the Dirac point of the device in Volts over time, shows that the Dirac point shifts downward towards the baseline Dirac voltage established in first step 541 during Sweep Numbers 0 to 10. The shift in the Dirac point of the device back towards the baseline Dirac point is indicative of the absence of analyte present in the channel region.

Fourth Step: Fourth step 544 of the experimental process is to return to the baseline reference position of the Dirac point of the device and is seen in experimental results 500 between Sweep Numbers 35 to 40.

During fourth step 544, the channel region of the device continues to be exposed to electrolyte buffer (i.e., that acts as a liquid top gate of the device) at the same constant concentration as in previous steps as shown in plot 525. Also, during fourth step 544, analyte is no longer present in the electrolyte buffer, as shown in plot 530 where the analyte concentration is shown at a constant zero concentration during fourth step 544.

Also, during fourth step 544, the device is configured to apply a positive dielectrophoretic (DEP) force (i.e., the DEP component of the device is configured to apply a positive dielectrophoretic force) in the channel region of the device. A positive DEP force is caused by applying V_{BG} , an AC bias (i.e., a voltage applied to the bottom gate electrode of the device) at a frequency (v) of 800 kHz. The frequency (v) of the AC bias of V_{BG} is seen in plot 515, where between Sweep Numbers 35 and 40, a constant frequency (v) of 800 kHz is plotted.

Simultaneously with applying V_{BG} in this manner, the Dirac point position is determined, in order to confirm that the Dirac point of the device reverts to the baseline Dirac point established in first step 541. The Dirac point is determined by observing the point at which current through the drain of the device, i.e., drain current (I_{D}), is minimal while the top gate voltage (V_{TG}) is swept across a range of voltages during each of Sweep Numbers 35 to 40 that includes the Dirac point. As seen in plot 510, the top gate voltage V_{TG} is swept across a range of voltages, and based on this, the Dirac point is determined as shown in plot 505. Plot 505, which depicts the Dirac point of the device in Volts over time, shows that the Dirac point has returned to, and remains constant at, the baseline Dirac point established during first step 541 during Sweep Numbers 0 to 10. The shift in the Dirac point of the device returning to the baseline Dirac point is indicative of the absence of analyte trapped in the channel region and is further confirmation that the shift in the Dirac point observed in second step 542 was caused by analyte trapped in the channel region of the device. The device may thus be used to evaluate the presence (or absence) of analyte as described by observing changes, such as the changes described above, in the Dirac point of the device.

### Single Step Current Sensing:

FIG. 5B presents six plots of experimental results 550 of electrical characteristics of a device according to the present invention and illustrates how the device according to the present invention may be used to trap analyte and evaluate the presence of analyte using current sensing. Each plot shares a common x-axis 585 that presents time with reference to “Sweep Numbers” (referring to voltage sweeps described above in connection with plot 510 of FIG. 5A), such that the electrical characteristics of the device according to the present invention are, in each case, presented as a function of time (i.e., “Sweep Number”). Horizontal lines in each plot are drawn at Sweep Number 10, Sweep Number 30 and Sweep Number 35 that demarcate four experimental steps: first step 591 between Sweep Numbers 0 and 10; second step 592 between Sweep Numbers 10 and 30; third step 593 between Sweep Numbers 30 and 35; and fourth step 594 between Sweep Numbers 35 and 40.

In experimental results 550, current sensing is performed using a device according to the present invention, in particular in conjunction with a flow cell configured to allow for switching of an electrolyte buffer solution interacting with the graphene channel of the device. Current sensing is a technique for evaluating the presence of analyte in a biological sample, where the channel region of the device is exposed to an electrolyte solution with the biological sample that may contain the target analyte. Current sensing works by sensing a change in the electrical properties of the GFET component of the device caused by the presence of target analyte in the channel region of the device, specifically, the interaction between the target analyte and the graphene channel of the device that affects the amount of current that flows between the drain and the source of the GFET component of the device, i.e., the drain current (I_{D}).

In connection with conducting current sensing, voltage potentials are applied to the device such that the device operates in a combined DEP and GFET regime. The electrical connections and voltage potentials applied to the device resulting in electrical characteristics seen in experimental results 550 are similar to the electrical connections described in connection with device 200 in FIG. 2.

In order to operate in the DEP regime, the bottom gate electrode of the device is connected to V_{BG} , an AC bias, characterized by a frequency (v) and a peak-to-peak voltage (V_{PP}). The voltage source supplying the AC bias of V_{BG} has control over both frequency (v) and peak-to-peak voltage (V_{PP}) of V_{BG} . The frequency (v) of V_{BG} is depicted in plot 565 where the y-axis represents frequency (v) in MHz. As described above, applying V_{BG} at certain frequencies causes the device (specifically, the edges formed where the graphene layer crosses the bottom gate electrode) to apply a dielectrophoretic force in a positive or negative direction (i.e., a force attracting analyte to the channel region or repelling analyte away from the channel region). As seen in plot 565, V_{BG} is applied to the bottom gate electrode at a frequency (v) of 800 KHZ between Sweep Number 0 and Sweep Number 30 causing the device to generate a positive dielectrophoretic force (P-DEP) to attract target analyte to the channel region of the device. Between Sweep Number 30 and Sweep Number 35, V_{BG} is applied to the bottom gate electrode at a frequency (v) of 8 MHz causing the device to generate a negative dielectrophoretic force (N-DEP) to repel target analyte from the channel region of the device. Between Sweep Number 35 and Sweep Number 40, V_{BG} is again applied to the bottom gate electrode at a frequency (v) of 800 kHz causing the device to generate a positive dielectrophoretic force (P-DEP) to attract target analyte to the channel region of the device. The peak-to-peak voltage (V_{PP}) of V_{BG} is depicted in plot 570 where the y-axis represents peak-to-peak difference in voltage in Volts (V). As seen in plot 570, the peak-to-peak voltage (V_{PP}) of V_{BG} remains constant throughout the course of the experiment.

In order to simultaneously operate the device in the GFET regime to apply current sensing for evaluating a sample for the presence of an analyte, the source electrode of the device is electrically connected to ground such that the GFET source is grounded. The drain electrode of the device is electrically connected to V_{D}, a DC bias, such that the electrical potential of the GFET drain differs from that of GFET source by a constant, i.e., a DC, voltage potential.

The top gate electrode of the device is connected to V_{TG} such that the electrical potential of top gate electrode, and therefore the electrical potential of electrolyte liquid top gate, of the device is set at a specified electrical potential. The voltage of V_{TG} applied to the top gate electrode is shown in plot 560 where the y-axis represents Volts (V). As seen, the voltage of V_{TG} in plot 560 remains at a constant DC bias throughout the experiment. As such, V_{TG} is held constant during the experiment, i.e., such that observed changes in drain current (I_{D}) of the device are not caused by changes in V_{TG} but instead are caused by the presence (or absence) of analyte in the channel region of the device.

Plot 575 presents the concentration of electrolyte buffer that is flowed over the channel region of the device forming the electrolyte liquid top gate of the device. As seen in plot 575, the electrolyte concentration in the electrolyte buffer used as electrolyte liquid top gate remains constant throughout the experiment (i.e., the concentration remains constant at each Sweep Number of 585).

Plot 580 presents the concentration of target analyte present in the electrolyte buffer solution. As seen in plot 580, target analyte is introduced into the electrolyte buffer solution (and therefore introduced to the channel region of the device) at a constant concentration starting at Sweep Number 10 and is no longer present after Sweep Number 30.

Using a device according to the present invention to evaluate a sample for the presence of an analyte by conducting current sensing proceeds according to the following four steps.

Some aspects of the experimental steps are identical to those described above in connection with using a device according to the present invention to evaluate a sample for the presence of an analyte by conducting Dirac point sensing and are not further described in detail again here. First Step: First step 591 of the experimental process is to establish a baseline reference drain current (I_{D}) of the device and is seen in experimental results 550 between Sweep Numbers 0 to 10.

During first step 591, the channel region of the device is exposed to electrolyte buffer (i.e., that acts as a liquid top gate of the device) at a constant concentration as shown in plot 575, but the electrolyte buffer includes no target analyte, as shown in plot 580 (where the analyte concentration is shown as zero during this time, i.e., first step 591).

Also, during first step 591, the device is configured to apply a positive dielectrophoretic (DEP) force (i.e., the DEP component of the device is configured to apply a positive dielectrophoretic force) in the channel region of the device. A positive DEP force is caused by applying V_{BG}, an AC bias (i.e., a voltage applied to the bottom gate electrode of the device), at a frequency (v) of 800 kHz. The frequency (v) of the AC bias of V_{BG} is seen in plot 565, where, during first step 591, between Sweep Numbers 0 and 10, a constant frequency (v) of 800 kHz is plotted, and plot 565 is annotated “P-DEP” referring to positive dielectrophoretic force. The peak-to-peak voltage (V_{PP}) of V_{BG} remains constant during first step 591 as seen in plot 570.

Simultaneously with applying V_{BG} in this manner, a baseline drain current (I_{D}) is determined in order to establish a reference for the drain current (I_{D}) before introducing target analyte. A baseline drain current (I_{D}) is determined by observing the drain current (I_{D}) during first step 591 corresponding to Sweep Numbers 0 to 10. Plot 555, which depicts the drain current (I_{D}) of the device in μA over time, shows that the drain current (I_{D}) is established at a constant current (approximately 60 μA) during first step 591 that occurs during Sweep Numbers 0 to 10.

Second Step: Second step 592 of the experimental process is to cause analyte response saturation and is seen in experimental results 550 between Sweep Numbers 10 to 30. During second step 592, the channel region of the device continues to be exposed to electrolyte buffer (i.e., that acts as a liquid top gate of the device) at the same constant concentration as in first step 591, as shown in plot 575. Also, during second step 592, analyte is introduced into the electrolyte buffer at a constant concentration, as shown in plot 580 (where the analyte concentration is shown at a constant, non-zero, concentration during second step 592).

Also, during the second step 592, the device continues to be configured to apply a positive dielectrophoretic (DEP) force (i.e., the DEP component of the device is configured to apply a positive dielectrophoretic force) in the channel region of the device. The positive DEP force continues to be caused by applying V_{BG} , an AC bias (i.e., a voltage applied to the bottom gate electrode of the device) at a frequency (v) of 800 kHz. The frequency (v) of the AC bias of V_{BG} is seen in plot 565, where, during second step 592, between Sweep Numbers 10 and 30, a constant frequency (v) of 800 kHz is plotted, and plot 565 is annotated “P-DEP” referring to positive dielectrophoretic force. Because a positive DEP force is generated in the channel region of the device, analyte present in the electrolyte buffer is trapped in the channel region of the device. Analyte trapped in the channel region of the device interacts with the graphene layer, changing the electrical properties of the graphene layer of the device such that the magnitude of the drain current (I_{D}) is expected to change in response to the presence of analyte trapped in the channel region.

Simultaneously with applying V_{BG} in this manner, a shift in the magnitude of the drain current (I_{D}), relative to the baseline drain current (I_{D}) established in first step 591, is observed as follows. The change in drain current (I_{D}) is determined in the same way the baseline drain current (I_{D}) is established in first step 591. That is, the change in drain current (I_{D}) is determined by observing the amount of current through the drain of the device, i.e., drain current (I_{D}), while all other variables (other than the presence of analyte in the channel region as seen in plot 580) are held constant, in particular while the top gate voltage (V_{TG}) is held constant, as seen in plot 560. Plot 555, which depicts the drain current (I_{D}) of the device in μA over time, shows that the drain current (I_{D}) shifted upwards to a higher magnitude of drain current (I_{D}) in the second step 592 during Sweep Numbers 10 to 30, relative to the baseline drain current (I_{D}) established during Sweep Numbers 0 to 10. The shift in the drain current (I_{D}) of the device is indicative of the presence of analyte trapped in the channel region such that the device may be used to evaluate the presence of analyte by observing changes, such as the change described above, in the drain current (I_{D}) of the device.

Third Step: Third step 593 of the experimental process is to de-trap the analyte in the channel region of the device and is seen in experimental results 550 between Sweep Numbers 30 to 35.

During third step 593, the channel region of the device continues to be exposed to electrolyte buffer (i.e., that acts as a liquid top gate of the device) at the same constant concentration as in the previous steps 591 592, as shown in plot 575. Also, during third step 593, analyte is no longer present in the electrolyte buffer, as shown in plot 580 where the analyte concentration is shown at a constant zero concentration during third step 593.

Also, during third step 593, the device is configured to apply a negative dielectrophoretic (DEP) force (i.e., the DEP component of the device is configured to apply a negative dielectrophoretic force) in the channel region of the device. The negative DEP force is caused by applying V_{BG} , an AC bias (i.e., a voltage applied to the bottom gate electrode of the device) at a frequency (v) of 8 MHz. This new frequency (v) of the AC bias of V_{BG} is seen in plot 565, where between Sweep Numbers 30 and 35, a constant frequency (v) of 8 MHz is applied, and plot 565 is annotated “N-DEP” referring to negative dielectrophoretic force. Because a negative DEP force is generated in the channel region of the device, analyte that had previously been trapped in the channel region of the device is now forced away from, and out of, the channel region. Whereas analyte trapped in the channel region of the device had previously interacted with the graphene layer of the device, changing the electrical properties of the graphene layer of the device (such that the drain current (I_{D}) is changed), the absence of analyte in the channel region removes such interaction between the analyte and the graphene layer of the device so that the drain current (I_{D}) is expected to revert to the baseline drain current (I_{D}) established in first step 591.

Simultaneously with applying V_{BG} in this manner, a change in the drain current (I_{D}) reverting to the baseline drain current (I_{D}) established in first step 591, is observed in third step 593 as follows. As described previously, the shifted drain current (I_{D}) is determined by observing the magnitude of the current through the drain of the device, i.e., drain current (I_{D}) while other variables, including the top gate voltage (V_{TG}) are held constant. As seen in plot 560, the top gate voltage V_{TG} is held constant during each of Sweep Numbers 30 to 35. Plot 555, which depicts the drain current (I_{D}) of the device in μA over time, shows that the drain current (I_{D}) shifted downward towards the baseline drain current (I_{D}) established in first step 591. The shift in the drain current (I_{D}) of the device back towards the baseline drain current (I_{D}) is indicative of the absence of analyte present in the channel region.

Fourth Step: Fourth step 594 of the experimental process is to return to the baseline reference position of the drain current (I_{D}) of the device and is seen in experimental results 550 between Sweep Numbers 35 to 40.

During fourth step 594, the channel region of the device continues to be exposed to electrolyte buffer (i.e., that acts as a liquid top gate of the device) at the same constant concentration as in previous steps as shown in plot 575. Also, during fourth step 594, analyte is no longer present in the electrolyte buffer, as shown in plot 580 where the analyte concentration is shown at a constant zero concentration during fourth step 594.

Also, during fourth step 594, the device is configured to apply a positive dielectrophoretic (DEP) force (i.e., the DEP component of the device is configured to apply a positive dielectrophoretic force) in the channel region of the device. A positive DEP force is caused by applying V_{BG} , an AC bias (i.e., a voltage applied to the bottom gate electrode of the device) at a frequency (v) of 800 kHz. The frequency (v) of the AC bias of V_{BG} is seen in plot 565, where between Sweep Numbers 35 and 40, a constant frequency (v) of 800 kHz is plotted.

Simultaneously with applying V_{BG} in this manner, the drain current (I_{D}) is determined, in order to confirm that the drain current (I_{D}) of the device reverted to the baseline drain current (I_{D}) established in first step 591. The drain current (I_{D}) is determined by observing the current through the drain of the device, i.e., drain current (I_{D}), while all other variables including the top gate voltage (V_{TG}) held constant during each of Sweep Numbers 35 to 40. Plot 555, which depicts the drain current (I_{D}) of the device in μA over time, shows that the drain current (I_{D}) returned to, and remained constant at, the baseline drain current (I_{D}) established during first step 591 during Sweep Numbers 0 to 10. The shift in the drain current (I_{D}) of the device returning to the baseline drain current (I_{D}) is indicative of the absence of analyte trapped in the channel region and is further confirmation that the shift in the drain current (I_{D}) observed in second step 592 was caused by analyte trapped in the channel region of the device. The device may thus be used to evaluate the presence (or absence) of analyte as described by observing changes, such as the changes described above, in the drain current (I_{D}) of the device.

### Dirac Point Tracking:

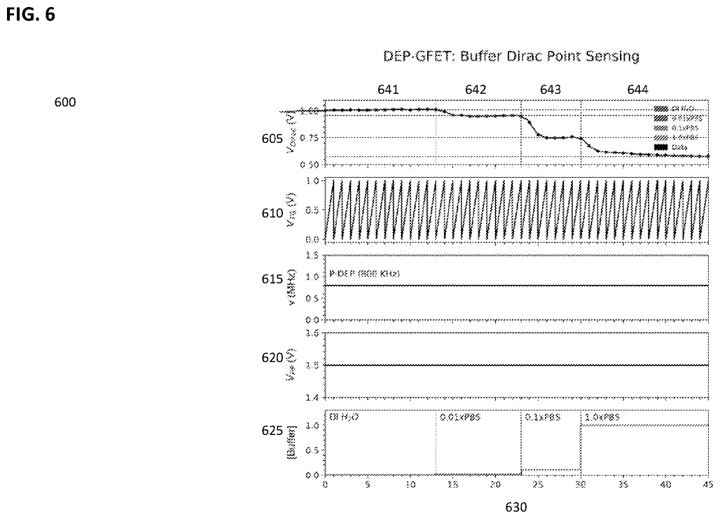

FIG. 6 presents five plots of experimental results 600 of electrical characteristics of a device according to the present invention and illustrates the ability to track the Dirac point of the device while the device simultaneously applies a positive DEP force. Each plot shares a common x-axis 630 that presents time with reference to “Sweep Numbers” (referring to voltage sweeps of V_{TG} ), such that the electrical characteristics of the device according to the present invention are, in each case, presented as a function of time (i.e., “Sweep Number”). Horizontal lines in each plot are drawn at Sweep Number 13, Sweep Number 23 and Sweep Number 30 that demarcate four experimental steps: first step 641 between Sweep Numbers 0 and 13; second step 642 between Sweep Numbers 13 and 23; third step 643 between Sweep Numbers 23 and 30; and fourth step 644 between Sweep Numbers 30 and 45.

The experiment, the results of which are depicted in FIG. 6, was performed with a flow cell and a syringe pump, to flow DI (de-ionized) H₂O, 0.01×PBS (Phosphate-buffered saline), 0.1×PBS and 1.0×PBS in sequential order over the channel region of the device, such that: the channel region of the device is exposed to de-ionized H₂O in first step 641; the channel region of the device is exposed to 0.01×PBS in second step 642; the channel region of the device is exposed to 0.1×PBS in third step 643; and the channel region of the device is exposed to 1.0×PBS in fourth step 644. During each step, the Dirac point of the device is monitored, showing that changes in the ion concentration of the electrolyte buffer that functions as the liquid top gate of the device affect the Dirac point of the device while the device simultaneously applies a positive dielectrophoretic force in the channel region.

In experimental results 600, Dirac point sensing is performed using a device according to the present invention, in particular in conjunction with a flow cell that is configured to allow for switching of an electrolyte buffer solution interacting with the graphene channel of the device.

Dirac point sensing works by sensing a change in the Dirac point of the GFET component of the device caused by, in the case of experimental results 600, different electrolyte concentrations in the electrolyte buffer flowed over the channel region of the device, specifically, the interaction between the electrolyte and the graphene layer of the device.

In connection with conducting Dirac point sensing to generate experimental results 600, voltage potentials are applied to the device such that the device operates in a combined DEP and GFET regime. The electrical connections and voltage potentials applied to the device resulting in electrical characteristics 600 are similar to the electrical connections described in connection with device 200 in FIG. 2 as well as those described in connection with experimental results 500 presented in FIG. 5A.

In order to operate in the DEP regime, the bottom gate electrode of the device is connected to V_{BG} , an AC bias, characterized by a frequency (v) and a peak-to-peak voltage (V_{PP}). The voltage source supplying the AC bias of V_{BG} has control over both frequency (v) and peak-to-peak voltage (V_{PP}) of V_{BG} . The frequency (v) of V_{BG} is depicted in plot 615 where the y-axis represents frequency (v) in MHz. As described above, applying V_{BG} at certain frequencies causes the device (specifically, the edges formed where the graphene layer crosses the bottom gate electrode) to apply a dielectrophoretic force in a positive or negative direction (i.e., a force attracting analyte to the channel region or repelling analyte away from the channel region). As seen in plot 615, V_{BG} is applied to the bottom gate electrode at a constant frequency (v) of 800 KHZ constant throughout the course of the experiment causing the device to generate a positive dielectrophoretic force (P-DEP) to attract target analyte to the channel region of the device. The peak-to-peak voltage (V_{PP}) of V_{BG} is depicted in plot 620 where the y-axis represents peak-to-peak difference in voltage in Volts (V). As seen in plot 620, the peak-to-peak voltage (V_{PP}) of V_{BG} remains constant throughout the course of the experiment.

In order to simultaneously operate in the GFET regime to apply Dirac point sensing, the source electrode of the device is electrically connected to ground such that the GFET source is grounded. The drain electrode of the device is electrically connected to VD, a DC bias, such that the electrical potential of the GFET drain differs from that of GFET source by a constant, i.e., a DC, voltage potential.

The top gate electrode of the device is connected to V_{TG} such that the electrical potential of top gate electrode, and therefore the electrical potential of electrolyte liquid top gate, of the device is swept between a low and a high voltage. The voltage sweep of V_{TG} applied to the top gate electrode is shown in plot 610 where the y-axis represents Volts (V). As seen, the voltage of V_{TG} in plot 610 exhibits a saw tooth pattern sweeping from a low voltage to a high voltage, once per each Sweep Number depicted on x-axis 630. As described above, the Dirac point of the GFET component of the device corresponds to the value of V_{TG} at which minimal drain current (I_{D}) is observed across the graphene layer of the channel region of the device. As such, V_{TG} is swept across a range of voltages that span the range of potential Dirac points in order to track a shift in the Dirac point during the experiment, i.e., a shift in the Dirac point of the GFET component of the device resulting from the different concentrations of electrolyte buffer flowed across the device, as seen in plot 625, and interacting with the graphene layer in the channel region of the device.

Plot 625 presents the concentration of electrolyte buffer that is flowed over the channel region of the device forming the electrolyte liquid top gate of the device. As seen in plot 625, the electrolyte concentration in the electrolyte buffer used as electrolyte liquid top gate changes throughout the experiment. As seen in plot 625, the channel region of the device is exposed to de-ionized H₂O in first step 641 (i.e., an electrolyte concentration of zero). The channel region of the device is exposed to 0.01×PBS in second step 642. The channel region of the device is exposed to 0.1×PBS in third step 643. The channel region of the device is exposed to 1.0×PBS in fourth step 644. During each step, while the device is exposed to different concentrations of electrolyte buffer, the Dirac point of the device is monitored, showing that changes in the ion concentration of the electrolyte buffer that functions as the liquid top gate of the device affect the Dirac point of the device while the device simultaneously applies a positive dielectrophoretic force in the channel region.

First Step: During the first step 641, the channel region of the device is exposed to electrolyte buffer (i.e., that acts as a liquid top gate of the device) comprising de-ionized water (i.e., an electrolyte buffer with electrolyte concentration of zero) as shown in plot 625.

While the channel region of the device is exposed to de-ionized water in first step 641, a Dirac point position of the device is determined. The Dirac point is determined by observing the point at which current through the drain of the device, i.e., drain current (I_{D}), is minimal while the top gate voltage (V_{TG}) is swept across a range of voltages during each of Sweep Numbers 0 to 13, where each voltage sweep includes the Dirac point. As seen in plot 610, the top gate voltage V_{TG} is swept across a range of voltages, and based on this, the Dirac point is determined as shown in plot 605. Plot 605, which depicts the Dirac point of the device in Volts over time, shows that the Dirac point is established at a constant voltage (approximately 1.0 Volts) during first step 641 that occurs during Sweep Numbers 0 to 13.

Second Step: During second step 642, the channel region of the device is exposed to electrolyte buffer (i.e., that acts as a liquid top gate of the device) comprising 0.01×PBS as shown in plot 625.

While the channel region of the device is exposed to 0.01×PBS in second step 642, a Dirac point position of the device is determined and a change in the Dirac point of the device is observed as compared to that in first step 641. As seen in plot 610, the top gate voltage V_{TG} is swept across a range of voltages during the second step, and based on this, the Dirac point is determined as shown in plot 605. Plot 605, which depicts the Dirac point of the device in Volts over time, shows that the Dirac point is established at a constant voltage (approximately 0.9 V) during second step 642 that occurs during Sweep Numbers 13 to 23. Thus, a change in the concentration of the electrolyte buffer is observed to cause a change in the Dirac point of the device.

Third Step: During third step 643, the channel region of the device is exposed to electrolyte buffer (i.e., that acts as a liquid top gate of the device) comprising 0.1×PBS as shown in plot 625.

While the channel region of the device is exposed to 0.1×PBS in third step 643, a Dirac point position of the device is determined and a change in the Dirac point of the device is observed as compared to that in second step 642 and first step 641. As seen in plot 610, the top gate voltage V_{TG} is swept across a range of voltages during third step 643, and based on this, the Dirac point is determined as shown in plot 605. Plot 605, which depicts the Dirac point of the device in Volts over time, shows that the Dirac point is established at a constant voltage (approximately 0.75 V) during third step 643 that occurs during Sweep Numbers 23 to 30. Thus, a change in the concentration of the electrolyte buffer is observed to cause a change in the Dirac point of the device.

Fourth Step: During fourth step 644, the channel region of the device is exposed to electrolyte buffer (i.e., that acts as a liquid top gate of the device) comprising 1.0×PBS as shown in plot 625.

While the channel region of the device is exposed to 1.0×PBS in fourth step 644, a Dirac point position of the device is determined and a change in the Dirac point of the device is observed as compared to that in third step 643, second step 642 and first step 641. As seen in plot 610, the top gate voltage V_{TG} is swept across a range of voltages during the fourth step, and based on this, the Dirac point is determined as shown in plot 605. Plot 605, which depicts the Dirac point of the device in Volts over time, shows that the Dirac point is established at a constant voltage (approximately 0.6 V) during fourth step 644 that occurs during Sweep Numbers 30 to 45. Thus, a change in the concentration of the electrolyte buffer is observed to cause a change in the Dirac point of the device.

### Dielectrophoretic (DEP) Trapping:

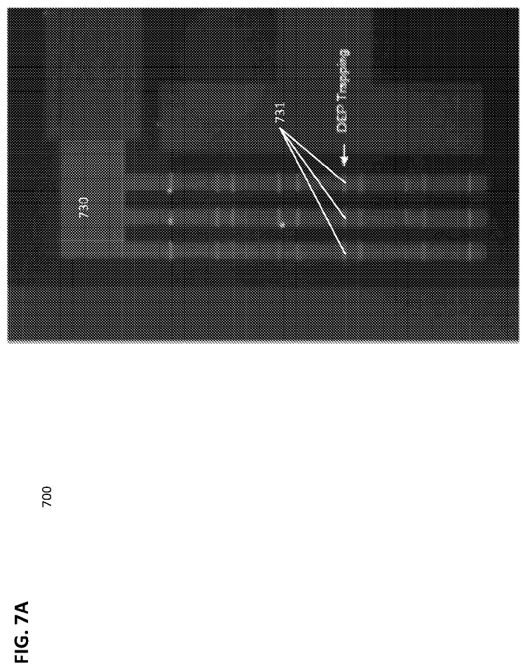

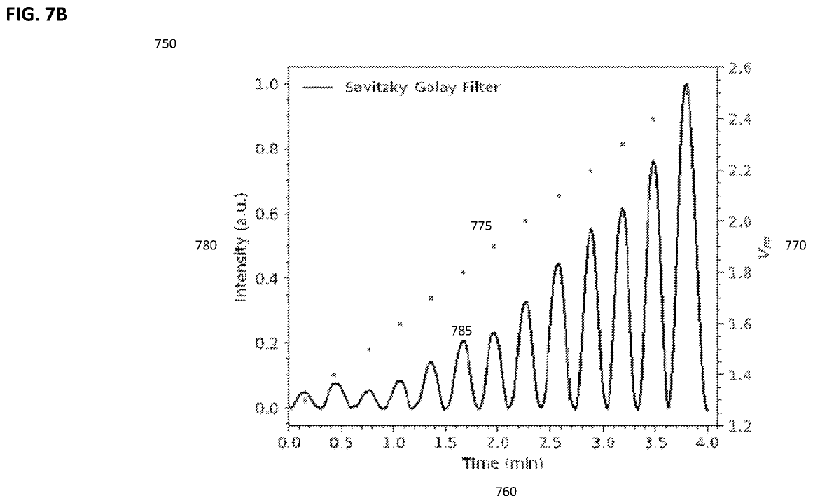

FIGS. 7A-7B present experimental results of using a device according to the present invention for dielectrophoretic (DEP) trapping. FIGS. 7A-7B illustrate as well as characterize the functionality of the DEP component of devices according to the present invention.

Fluorescence (FL) microscopy is a standard characterization technique for analyzing DEP trapping. FIGS. 7A-7B detail the DEP trapping experiments performed using green fluorescent dyed 42 nm polystyrene (PS) beads using an embodiment of a DEP-GFET device according to the present invention. DEP trap sites are located within the channel region of the device at the intersection of the graphene channel edge and the local back gate electrode 730 (for example, edges 231 in FIG. 2). Representative trap sites 731 are identified in FIG. 7A.

Back gate electrode 730 including its interdigitated configuration is seen in FIG. 7A; however, the graphene layer of the device is identifiable in FIG. 7A only by reference to representative trap sites 731, i.e., as a silhouette.

For the device depicted in FIG. 7A, DEP trapping occurs when applying an AC bias, V_{BG}, to bottom gate electrode of device, with a frequency (v) of 800 kHz over a range of peak-to-peak voltages (V_{PP}). The image in FIG. 7A was taken when applying an AC bias, V_{BG}, at a frequency (v) of 800 kHz and a peak-to-peak voltage (V_{PP}) of 2.5 V.

FIG. 7B presents a plot of results 750 of monitoring trap site (e.g., edges 731) pixel positions on the device pictured in FIG. 7A throughout a sweep (comprising steps from 1.3 to 2.5 V) of the peak-to-peak voltage (V_{PP}) of V_{BG}. Peak-to-peak voltage (V_{PP}) of V_{BG} 770 is presented with reference to the right-hand side of plot 750 where each dot 755 represents a peak-to-peak voltage (V_{PP}) of V_{BG} at the corresponding time 760 presented on the x-axis of the plot of results 750. Trap site (e.g., edges 731) pixel positions were monitored on the device by measuring light intensity of trap site pixel positions. Light intensity 780 is presented with reference to the left-hand side of plot 750 where line 785 represents light intensity of trap site pixel positions over time 760 (i.e., as V_{PP} of V_{BG} is varied). A Savitzky-Golay filter was applied to light intensity data 785 for the purpose of smoothing the data, and baseline correction was applied to the raw light intensity data measurements for the purpose of correcting any drift in baseline intensity over time. The processed light intensity data 785 shows that max peak fluorescence (FL) intensity increases parabolically with a linear increase in V_{PP} at a fixed V_{BG} trapping frequency (v) of 800 kHz. The increasing fluorescence (FL) intensity 785 response represents an increased number of the trapped target analyte (i.e., the number of fluorescent dyed PS beads, in the case of results 750 presented in FIG. 7B) at the graphene edge trap sites.

Notwithstanding the appended claims, the invention may be defined by the following clauses:
1. A bifunctional graphene dielectrophoresis (DEP)-graphene field effect transistor (GFET) device, the device comprising:
   a graphene dielectrophoresis (DEP) component; and
   a graphene field effect transistor (GFET) component;
   wherein the graphene DEP and GFET components are independently operable.
2. The device according to clause 1, wherein the graphene DEP component comprises:
   a graphene layer;
   a source electrode electrically connected to the graphene layer; and a bottom gate electrode separated from the graphene layer by a dielectric layer.
3. The device according to clause 2, wherein the GFET component comprises:
   the graphene layer;
   the source electrode;
   a drain electrode electrically connected to the graphene layer and separated from the source electrode; and
   a top gate electrode separated from the graphene layer, the source and drain electrodes and the bottom gate electrode.
4. The device according to clause 3, further comprising:
   a substrate supporting the DEP component and the GFET component comprising an electrically insulating layer configured so that the bottom gate electrode is embedded within the electrically insulating layer; and
   a channel region located between the source and drain electrodes, wherein the graphene layer is present within the channel region and the bottom gate electrode is present beneath the channel region.
5. The device according to clause 4, wherein the channel region is configured to receive fluid.
6. The device according to clause 5, wherein the top gate electrode is configured to electrically influence a fluid present in the channel region.
7. The device according to clause 6, wherein the top gate electrode and the fluid present in the channel region comprise a top gate.
8. The device according to clause 7, further comprising an electrical passivation layer present on the source and drain electrodes.
9. The device according to clause 8, wherein the electrical passivation layer is configured to minimize current leakage between the top gate and the source and drain electrodes.
10. The device according to any of clauses 4 to 9, wherein the channel region comprises a plurality of laterally spaced strips of graphene layers.
11. The device according to any of clauses 4 to 10, wherein the bottom gate electrode is configured in an interdigitated fashion.
12. The device according to any of clauses 2 to 11, wherein a thickness of the dielectric layer is less than 20 nm.
13. The device according to any of clauses 2 to 11, wherein a dielectric constant of the dielectric layer is greater than four.
14. The device according to any of clauses 2 to 13, wherein the graphene layer comprises surface functionalization configured to enhance specificity of an analyte attracted to the graphene layer.
15. The device according to clause 14, wherein the surface functionalization comprises a probe for the analyte.
16. The device according to clause 15, wherein the probe specifically binds to the analyte.
17. The device according to clause 16, wherein the probe comprises an antibody or binding fragment thereof.
18. The device according to clause 16, wherein the probe comprises a nucleic acid.
19. The device according to any of clauses 15 to 18, wherein the probe is stably associated with a surface of the graphene layer.
20. The device according to clause 19, wherein the stable association comprises a covalent bond.
21. The device according to any of clauses 14 to 20, wherein the surface functionalization further comprises a second probe for a second analyte.
22. The device according to any of clauses 2 to 21, further comprising a cover layer configured to form an isolated microfluidic region over the graphene layer.
23. The device according to any of the previous clauses, wherein the device comprises two or more distinguishable subunits, each comprising a DEP component and a GFET component, wherein the subunits are independently operable.
24. The device according to clause 23, wherein the two or more subunits are supported on a common substrate.
25. The device according to any of clauses 23 to 24, further comprising a cover layer configured to form isolated microfluidic regions over each subunit.
26. The device according to clause 25, wherein the isolated microfluidic regions are microfluidic wells.
27. The device according to any of clauses 25 to 26, wherein the isolated microfluidic regions are configured to expose graphene layers of the subunits.
28. The device according to any of clauses 25 to 27, wherein each isolated microfluidic region is associated with at least two subunits.
29. The device according to any of clauses 23 to 28, wherein the subunits comprise surface functionalization configured to attract different analytes to different subunits.
30. The device according to any of the previous clauses, wherein the device is a component of a multiplex analyte sensing chip.
31. A system comprising:
   a bifunctional graphene dielectrophoresis (DEP)-graphene field effect transistor (GFET) device, the device comprising:
   a graphene dielectrophoresis (DEP) component; and
   a graphene field effect transistor (GFET) component;
   wherein the graphene DEP and GFET components are independently operable; and
   a voltage source configured to output a plurality of independent voltages and operably connected to the device.
32. The system according to clause 31, wherein the graphene DEP component comprises:
   a graphene layer;
   a source electrode electrically connected to the graphene layer; and
   a bottom gate electrode separated from the source electrode by a dielectric layer.
33. The system according to clause 32, wherein the voltage source is configured to apply a bottom gate bias (V_{BG}) to the bottom gate electrode.
34. The system according to clause 33, wherein the bottom gate bias (V_{BG}) is an AC bias with a specified frequency (v) and peak-to-peak voltage (V_{PP}) .
35. The system according to any of clauses 32 to 34, wherein the GFET component comprises:
   the graphene layer;
   the source electrode;
   a drain electrode electrically connected to the graphene layer and separated from the source electrode; and
   a top gate electrode separated from the graphene layer, the source and drain electrodes and the bottom gate electrode.
36. The system according to clause 35, wherein the voltage source is configured to apply a drain bias (V_{D}) to the drain electrode.
37. The system according to clause 36, wherein the drain bias (V_{D}) is a DC bias.
   38. The system according to any of clauses 35 to 37, wherein the voltage source is configured to apply a top gate bias (V_{TG}) to the top gate electrode.
39. The system according to clause 38, wherein the top gate bias (V_{TG}) is a DC bias.
40. The system according to clause 38, wherein the top gate bias (V_{TG}) comprises a voltage sweep.
41. The system according to clause 40, wherein the top gate bias (V_{TG}) voltage sweep spans a Dirac voltage of the device.
42. The system according to any of clauses 32 to 41, wherein the source electrode is electrically connected to ground.
43. The system according to any of clauses 31 to 42, further comprising a sensor operably connected to the device and configured to sense an electrical characteristic of the device.
44. The system according to clause 43, wherein the sensor comprises a circuit configured to sense an electrical characteristic of the device.
45. The system according to any of clauses 43 to 44, wherein the sensor is embedded within the device.
46. The system according to any of clauses 43 to 45, wherein the sensor is configured to sense current between the source electrode and the drain electrode.
47. The system according to any of clauses 43 to 45, wherein the sensor is configured to sense voltage between the source electrode and the drain electrode.
48. The system according to any of clauses 43 to 47, further comprising a controller operably connected to the sensor and configured to detect a change in an electrical characteristic of the device sensed by the sensor.
49. The system according to any of clauses 43 to 48, further comprising a transmitter configured to transmit an output of the sensor.
50. The system according to clause 48, further comprising a transmitter configured to transmit an output of the controller.
51. The system according to any of clauses 49 to 50, wherein the transmitter is a wireless transmitter.
52. The system according to any of clauses 31 to 51,
   wherein the device comprises two or more distinguishable subunits, each comprising a DEP component and a GFET component, wherein the subunits are independently operable, and
   wherein the voltage source is operably connected to each of the subunits.
53. The system according to clause 50, wherein the system is a multiplex analyte sensing chip.
54. A method of evaluating a sample for the presence of an analyte, the method comprising:
   introducing the sample into a bifunctional graphene dielectrophoresis (DEP)-graphene field effect transistor (GFET) device comprising:
   a graphene dielectrophoresis (DEP) component; and
   a graphene field effect transistor (GFET) component;
   wherein the graphene DEP and GFET components are independently operable; and
   obtaining a result from the device providing information as to whether the analyte is present in the sample.
55. The method according to clause 54, wherein the graphene DEP component of the device comprises:
   a graphene layer;
   a source electrode electrically connected to the graphene layer; and
   a bottom gate electrode separated from the source electrode by a dielectric layer.
56. The method according to clause 55, further comprising applying a bottom gate bias (V_{BG}) to the bottom gate electrode sufficient to cause the graphene layer to apply a dielectrophoretic force.
57. The method according to clause 56, wherein the bottom gate bias (V_{BG}) is an AC bias comprising a specified frequency (v) and a specified peak-to-peak voltage (V_{PP}) .
58. The method according to clause 57, wherein the peak-to-peak voltage (V_{PP}) is held constant.
59. The method according to clause 57, wherein the peak-to-peak voltage (V_{PP}) is not held constant.
60. The method according to any of clauses 56 to 59, wherein the graphene layer applies the dielectrophoretic force within a device channel region located between the source and drain electrodes, wherein the graphene layer is present within the channel region.
61. The method according to any of clauses 56 to 60, wherein the dielectrophoretic force is a positive dielectrophoresis force.
62. The method according to any of clauses 56 to 61, wherein the dielectrophoretic force is a negative dielectrophoresis force.
63. The method according to any of clauses 54 to 62, wherein the GFET component of the device comprises:
   the graphene layer;
   the source electrode;
   a drain electrode electrically connected to the graphene layer and separated from the source electrode; and
   a top gate electrode separated from the graphene layer, the source and drain electrodes and the bottom gate electrode.
64. The method according to clause 63, wherein obtaining a result from the device providing information as to whether the analyte is present in the sample comprises:
   exposing the graphene layer to the sample;
   simultaneously applying a drain bias (V_{D}) comprising a DC bias to the drain electrode and a top gate bias (V_{TG}) to the top gate electrode; and
   measuring an electrical property of the device.
65. The method according to clause 64,
   wherein the top gate bias (V_{TG}) is a DC bias, and
   wherein measuring the electrical property of the device comprises measuring a drain current.
66. The method according to clause 65,
   wherein the top gate bias (V_{TG}) comprises a voltage sweep, and
   wherein measuring the electrical property of the device comprises measuring a Dirac point response of the device.
67. The method according to clause 66, wherein the top gate bias (V_{TG}) voltage sweep spans a Dirac voltage of the device.
68. The method according to any of clauses 64 to 67, exposing the graphene layer to the sample comprises applying a bottom gate bias (V_{BG}) to the bottom gate electrode sufficient to cause the graphene layer to apply a dielectrophoretic force.
69. The method according to any of clauses 54 to 68, further comprising using a flow cell to flow fluid over the device.
70. A kit for attracting and sensing analyte, the kit comprising:
   a device according to any of clauses 1 to 30; and
   packaging for the device.
71. The kit according to clause 70, further comprising a power supply for the device.
72. The kit according to any of clauses 70 to 71, wherein the packaging for the device comprises a cartridge configured to house the device.
73. The kit according to any of clauses 70 to 72, further comprising a sample collection device.
74. The kit according to clause 73, wherein the sample collection device comprises sample transport media.
75. The kit according to any of clauses 70 to 74, wherein the device is a component of a multiplex analyte sensing chip.
76. The kit according to clause 75, wherein the multiplex analyte sensing chip comprises a control.
77. The kit according to clause 76, wherein the control comprises a positive control.
78. The kit according to clause 76, wherein the control comprises a negative control.
79. A kit for attracting and sensing analyte, the kit comprising:
   a system according to any of clauses 31 to 53; and
   packaging for the system.

In at least some of the previously described embodiments, one or more elements used in an embodiment can interchangeably be used in another embodiment unless such a replacement is not technically feasible. It will be appreciated by those skilled in the art that various other omissions, additions and modifications may be made to the methods and structures described above without departing from the scope of the claimed subject matter. All such modifications and changes are intended to fall within the scope of the subject matter, as defined by the appended claims.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations.

However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible sub-ranges and combinations of sub-ranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into sub-ranges as discussed above. Finally, as will be understood by one skilled in the art, a range includes each individual member. Thus, for example, a group having 1-3 articles refers to groups having 1, 2, or 3 articles. Similarly, a group having 1-5 articles refers to groups having 1, 2, 3, 4, or 5 articles, and so forth.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art and are to be construed as being without limitation to such specifically recited examples and conditions.

Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. Moreover, nothing disclosed herein is intended to be dedicated to the public regardless of whether such disclosure is explicitly recited in the claims.

The scope of the present invention, therefore, is not intended to be limited to the exemplary embodiments shown and described herein. Rather, the scope and spirit of present invention is embodied by the appended claims. In the claims, 35 U.S.C. § 112(f) or 35 U.S.C. § 112(6) is expressly defined as being invoked for a limitation in the claim only when the exact phrase “means for” or the exact phrase “step for” is recited at the beginning of such limitation in the claim; if such exact phrase is not used in a limitation in the claim, then 35 U.S.C. § 112(f) or 35 U.S.C. § 112(6) is not invoked.

What is claimed is:

1. A bifunctional graphene dielectrophoresis (DEP)-graphene field effect transistor (GFET) device, the device comprising:
a graphene dielectrophoresis (DEP) component; and
a graphene field effect transistor (GFET) component;
wherein the graphene DEP and GFET components are independently operable.

2. The device according to claim 1, wherein the graphene DEP component comprises:
a graphene layer;
a source electrode electrically connected to the graphene layer; and
a bottom gate electrode separated from the graphene layer by a dielectric layer.

3. The device according to claim 2, wherein the GFET component comprises:
the graphene layer;
the source electrode;
a drain electrode electrically connected to the graphene layer and separated from the source electrode; and
a top gate electrode separated from the graphene layer, the source and drain electrodes and the bottom gate electrode.

4. The device according to claim 3, further comprising:
a substrate supporting the DEP component and the GFET component comprising an electrically insulating layer configured so that the bottom gate electrode is embedded within the electrically insulating layer; and
a channel region located between the source and drain electrodes, wherein the graphene layer is present within the channel region and the bottom gate electrode is present beneath the channel region.

5. The device according to claim 4, wherein the channel region is configured to receive fluid.

6. The device according to claim 5, wherein the top gate electrode is configured to electrically influence a fluid present in the channel region.

7. The device according to claim 6, wherein the top gate electrode and the fluid present in the channel region comprise a top gate.

8. The device according to claim 7, further comprising an electrical passivation layer present on the source and drain electrodes.

9. The device according to claim 8, wherein the electrical passivation layer is configured to minimize current leakage between the top gate and the source and drain electrodes.

10. The device according to any of the previous claims, wherein the device comprises two or more distinguishable subunits, each comprising a DEP component and a GFET component, wherein the subunits are independently operable.

11. The device according to claim 10, wherein the two or more subunits are supported on a common substrate.

12. The device according to any of the previous claims, wherein the device is a component of a multiplex analyte sensing chip.

13. A system comprising:
a bifunctional graphene dielectrophoresis (DEP)-graphene field effect transistor (GFET) device, the device comprising:
a graphene dielectrophoresis (DEP) component; and
a graphene field effect transistor (GFET) component;
wherein the graphene DEP and GFET components are independently operable; and
a voltage source configured to output a plurality of independent voltages and operably connected to the device.

14. A method of evaluating a sample for the presence of an analyte, the method comprising:
introducing the sample into a bifunctional graphene dielectrophoresis (DEP)-graphene field effect transistor (GFET) device comprising:
a graphene dielectrophoresis (DEP) component; and
a graphene field effect transistor (GFET) component;
wherein the graphene DEP and GFET components are independently operable; and
obtaining a result from the device providing information as to whether the analyte is present in the sample.

15. A kit for attracting and sensing analyte, the kit comprising:
a device according to any of claims 1 to 12; and
packaging for the device.
